(19) United States
(12) Patent Application Publication
(10) Pub. No.: US 2004/0067616 A1
(43) Pub. Date: Apr. 8, 2004

(54) Method of manufacturing semiconductor device

(75) Inventors: Atsushi Hachisuka, Tokyo (JP); Atsushi Amo, Tokyo (JP); Tatsuo Kasaoka, Tokyo (JP); Shunji Kubo, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: MITSUBISHI DENKI KABUSHIKI KAISHA, Tokyo (JP)

(21) Appl. No.: 10/369,724

(22) Filed: Feb. 21, 2003

(30) Foreign Application Priority Data
Oct. 2, 2002 (JP) 2002-289712

(51) Int. Cl. H01L 21/8242

(52) U.S. Cl. 438/241

(57) ABSTRACT

A technique for making it possible to miniaturize a semiconductor device having a memory device and a logic device on one semiconductor substrate even when a self-aligned process can not be utilized, i.e., a contact hole can not be self-aligned to a gate electrode. Contact holes (15, 65) are formed in an insulating layer (19) such that the contact holes (15) are located beside gate electrodes 6 while the contact holes (65) are located beside gate electrodes (56). An insulating film 35 is formed on each side face of the contact holes (15, 65). Then, contact plugs (16) filling the contact holes (15) and contact plugs (66) filling the contact holes (65) are formed.

### BACKGROUND OF THE INVENTION

1. Field of the Invention

The present invention relates to a method of manufacturing a semiconductor device in which a memory device and a logic device are formed, while being combined, on a semiconductor substrate.

2. Description of the Background Art

FIGS. 26 through 38 are sectional views for illustrating a conventional method of manufacturing a semiconductor device with a memory device and a logic device which are provided on one semiconductor substrate, in order of occurrence of respective steps. A typical semiconductor device with a memory device and a logic device employs a DRAM which includes a memory cell having a capacitor-under-bit line (CUB) structure, for example, as the memory device, and employs a dual gate salicide CMOS transistor (dual gate CMOS transistor formed by a salicide CMOS process), for example, as the logic device. Below, the conventional method of manufacturing a semiconductor device will be described with reference to FIGS. 26 through 38.

First, referring to FIG. 26, an isolation insulating film 2 is formed in a top face of a semiconductor substrate 1 of an n-type silicon substrate, for example, by using a well-known LOCOS isolation technique or trench isolation technique. Then, p-type well regions 3, 53 and an n-type well region 54 are formed in the top face of the semiconductor substrate 1. Specifically, the well region 53 is formed in a portion of the top face of the semiconductor substrate included in a region where the memory device is to be formed (hereinafter, referred to as a “memory formation region”), and the well region 54 is formed in a bottom portion of the well region 53. The well region 3 is formed in another portion of the top face of the semiconductor substrate 1 included in a region where the logic device is to be formed (hereinafter, referred to as a “logic formation region”). Subsequently, channel doping is carried out.

Next, a plurality of gate structures 61 regularly spaced from one another are formed on a portion of the semiconductor substrate 1 included in the memory formation region. Each of the gate structures 61 includes a gate insulating film 55 made of silicon oxide, for example, a gate electrode 56 made of polycrystalline silicon, for example, and a silicon oxide film 57 made of TEOS, for example, which are deposited sequentially in the order noted. Also, a plurality of gate structures 11 regularly spaced from one another are formed on another portion of the semiconductor substrate 1 included in the logic formation region. Each of the gate structures 11 includes a gate insulating film 5 made of silicon oxide, for example, a gate electrode 6 made of polycrystalline silicon, for example, and a silicon oxide film 7 made of TEOS, for example, which are deposited sequentially in the order noted.

Then, ions of impurities such as phosphorus or arsenic are implanted into the top face of the semiconductor substrate 1 at a relatively low concentration using the gate structures 11, 61 and the isolation insulating film 2 as a mask. As a result, n⁻-type impurity regions 58a are formed in the portion of the top face of the semiconductor substrate 1 included in the memory formation region, and n⁻-type impurity regions 8a are formed in the portion of the top face of the semiconductor substrate 1 included in the logic formation region.

Subsequently, referring to FIG. 27, a silicon nitride film is formed on an entire surface of the resultant structure by a CVD process, for example, and then is etched by anisotropic dry etching which provides a high etch rate in a direction along a depth of the semiconductor substrate 1. As a result, a sidewall 60 is formed on each side face of the gate structures 61, and a sidewall 10 is formed on each side face of the gate structures 11.

Thereafter, ions of impurities such as phosphorus or arsenic are implanted into the top face of the semiconductor substrate 1 at a relatively high concentration using the gate structures 11, 61, the isolation insulating film 2 and the sidewalls 10, 60, as a mask. As a result, n⁺-type impurity regions 58b are formed in the portion of the top face of the semiconductor substrate 1 included in the memory formation region, and n⁺-type impurity regions 8b are formed in the portion of the top face of the semiconductor substrate 1 included in the logic formation region.

By the foregoing steps, a plurality of source/drain regions 59 regularly spaced from one another, each of which is composed of the impurity regions 58a and 58b, are formed in the portion of the top face of the semiconductor substrate included in the memory formation region. Each of the gate structures 61 is located on a portion of the top face of the semiconductor substrate 1 between every two adjacent source/drain regions 59. Also, a plurality of source/drain regions 9 regularly spaced from one another, each of which is composed of the impurity regions 8a and 8b, are formed in the portion of the top face of the semiconductor substrate 1 included in the logic formation region. Each of the gate structures 11 is located on a portion of the top face of the semiconductor substrate 1 between every two adjacent source/drain regions 9.

The impurity regions 8b, 58b are formed so as to extend deeper than the impurity regions 8a and 58a for the reasons discussed as follows. Cobalt silicide films 12, which are to be formed on the semiconductor substrate 1 at a later stage and will be detailed later in the instant description, may happen to extend in part so deep as to be electrically connected with the well regions 3, 53. In order to avoid such situation, the impurity regions 8b, 58b are formed so as to extend deeper than the impurity regions 8a, 58a. Further, in this connection, to set an impurity concentration of the impurity regions 58b at an extremely high value would result in increase in leakage current flowing in a direction along a channel length, to possibly degrade charge retention characteristics (in other words, refresh characteristics) of the memory device. In order to prevent such degradation, the impurity concentration of the impurity regions 58b in the memory formation region is set to be lower than that of the impurity regions 8b in the logic formation region.

Turning to FIG. 28, the silicon oxide film 57 included in each of the gate structures 61 and the silicon oxide film 7 included in each of the gate structures 11 are removed using hydrofluoric acid, for example.

Next, a cobalt film is formed on an entire surface of the resultant structure by sputtering, for example. Then, annealing is carried out using a lamp annealer, for example, to cause cobalt of the cobalt film and silicon being in contact with the cobalt to react with each other. As a result, portions of the top face of the semiconductor substrate 1, as well as respective top faces of the gate electrodes 6, 56, are silicided, so that the cobalt silicide films 12 located on the source/drain regions 9, 59 and on the gate electrodes 6, 56 are formed, as illustrated in FIG. 29. Thus, the gate structures 11 each including the gate electrode 6 and the cobalt silicide film 12 on the gate electrode 6, and the gate structures 61 each including the gate electrode 56 and the cobalt silicide film 12 on the gate electrode 56, are formed. After that, portions of the cobalt film which remain un-reacted are removed.

Next, referring to FIG. 30, an insulating layer 19 including a stopper layer 13 and an interlayer insulating film 14 and covering the gate electrodes 11 and 61 are formed on the semiconductor substrate 1. More specifically, first, the stopper layer 13 is formed on an entire surface of the resultant structure. Subsequently, the interlayer insulating film 14 is formed on the stopper layer 13, and then is planarized by a CMP process or the like. As a result, the insulating layer 19 having a flat top face is formed on the semiconductor substrate 1. Additionally, a silicon nitride film, for example, is employed as the stopper layer 13, while a BPTEOS film, for example, is employed as the interlayer insulating film 14.

Next, referring to FIG. 31, contact plugs 116, 166 are formed in the insulating layer 19. More specifically, first, the interlayer insulating film 14 is etched to be partially removed using a photoresist (not illustrated) having a predetermined pattern of openings as a mask and using the stopper layer 13 as an etch stop. Subsequently, the photoresist is removed, and then exposed portions of the stopper layer 13 are etched to be removed. As a result, contact holes 165 reaching the cobalt silicide films 12 on the portion of the semiconductor substrate 1 in the memory formation region, and contact holes 115 reaching the cobalt silicide films 12 on the portion of the semiconductor substrate 1 in the logic formation region, are formed in the insulating layer 19.

Next, the contact plugs 116 filling the contact holes 115 and the contact plugs 166 filling the contact holes 165 are formed. Each of the contact plugs 116, 166 includes a stacked film of a barrier metal layer made of titanium nitride or the like and a high melting point metal layer such as titanium, tungsten or the like. Accordingly, the source/drain regions 59 are electrically connected to the contact plugs 166, while the source/drain regions 9 are electrically connected to the contact plugs 116. Further, contact plugs electrically connected to the gate electrodes 56 or 6 via the cobalt silicide films 12 are formed in the insulating layer 19, illustration of which is omitted in the drawings.

Next, referring to FIG. 32, a stopper layer 117 made of silicon nitride, for example, is formed on an entire surface of the resultant structure.

Next, referring to FIG. 33, an interlayer insulating film 118 is formed on the stopper layer 117. A BPTEOS film is employed as the interlayer insulating film 118, for example. The interlayer insulating film 118 is etched to be partially removed using a photoresist (not illustrated) having a predetermined pattern of openings as a mask and using the stopper layer 117 as an etch stop. Subsequently, the photoresist is removed, and then exposed portions of the stopper layer 117 are etched to be removed. As a result, openings 169 by which some of the contact plugs 166 are exposed are formed in the interlayer insulating film 118 and the stopper layer 117.

Thereafter, capacitors of the memory cell of the DRAM which are in contact with the contact plugs 166 are formed in the openings 169. More specifically, first, respective lower electrodes 170 of the capacitors each containing a high melting point metal such as ruthenium are formed in the openings 169, as illustrated in FIG. 34. Then, respective dielectric films 171 and respective upper electrodes 172 of the capacitors are formed, to complete the capacitors in the openings 169, as illustrated in FIG. 35. Each of the dielectric films 171 is made of tantalum pentoxide, while each of the upper electrodes 172 contains a high melting point metal such as ruthenium.

Next, referring to FIG. 36, an interlayer insulating film 123 made of TEOS, for example, is formed on the upper electrodes 172 of the capacitors and the interlayer insulating film 118, and then is planarized by a CMP process. Thereafter, contact holes 124, 174 are formed in the interlayer insulating film 118 and 123 and the stopper layer 117. The contact holes 124 extend from a top face of the interlayer insulating film 123, to reach the contact plugs 116. The contact holes 174 extend from the top face of the interlayer insulating film 123, to reach some of the contact plugs 166 which are not in contact with the capacitors.

For formation for the contact holes 124 and 174, first, the interlayer insulating films 118 and 123 are etched to be partially removed using a photoresist (not illustrated) having a predetermined pattern of openings as a mask and using the stopper layer 117 as an etch stop. Subsequently, the photoresist is removed, and then exposed portions of the stopper layer 117 are etched to be removed. Further, contact holes extending from the top face of the interlayer insulating film 123 and reaching the upper electrodes 172 are formed in the interlayer insulating film 123, illustration of which is omitted in the drawings.

Next, referring to FIG. 37, contact plugs 125 filling the contact holes 124 and contact plugs 175 filling the contact holes 174 are formed. Each of the contact plugs 125 and 175 includes a stacked film of a barrier metal layer made of titanium nitride or the like and a high melting point metal layer such as titanium or tungsten.

Next, referring to FIG. 38, interconnects 129 are formed in contact with the contact plugs 125 and interconnects 179 are formed in contact with the contact plugs 175, on the interlayer insulating film 123. Each of the interconnects 129 is formed of an aluminum interconnect 127 vertically interposed between titanium nitride layers 126 and 128. Analogously to the interconnects 129, each of the interconnects 179 is formed of an aluminum interconnect 177 vertically interposed between titanium nitride layers 176 and 178.

By the foregoing steps, the memory device and the logic device are formed in the memory formation region and the logic formation region, respectively.

The above-described conventional method corresponds to a method described in an antecedent patent application filed in Japan by an applicant which is also an owner of the present invention. It is additionally noted that the application number of the antecedent Japanese patent application is 2002-090483.

Also, Japanese patent application Laid-Open Nos. 8-107188, 11-307742. and 2000-307085 are cited herein as prior art references describing a semiconductor device including a DRAM memory cell.

In accordance with the above-described conventional method of manufacturing a semiconductor device, only the cobalt silicide films 12 are provided between a top face of each of the gate electrodes 6, 56 and the stopper layer 13, between which no insulating film is provided, as illustrated in FIG. 31. For this reason, a self-aligned process can not be utilized for formation of the contact holes 115 and the contact holes 165, i.e., the contact holes 115 and the contact holes 165 can not be self-aligned to the gate electrodes 6 and the gate electrodes 56, respectively, during formation thereof. Thus, alignment error or the like may cause any one of the contact holes 115 to be formed above any one of the gate electrodes 6, so that the cobalt silicide film 12 on the one of the gate electrodes 6 is exposed. This invites formation of a short-circuit between the one of the gate electrode 6 and one of the contact plugs 116 formed in the one of the contact holes 115 above the one of the gate electrodes 6. For the same reason as noted above, any one of the contact holes 165 may possibly be formed above any one of the gate electrodes 56, so that the cobalt silicide film 12 on the one of the gate electrodes 56 is exposed, to invite formation of a short-circuit between the one of the gate electrode 56 and one of the contact plugs 166 formed in the one of the contact holes 165 above the one of the gate electrodes 56.

As such, in the conventional method, it is necessary to take into account three parameters as follows in determining a design value of a distance m (see FIG. 31) between each of the contact holes 115 and each of the gate electrodes 6 adjacent to each other, or each of the contact holes 165 and each of the gate electrodes 56 adjacent to each other, in order to avoid formation of a short-circuit between the contact plugs 116 or 166 and the gate electrodes 6 or 56. The three parameters are: (1) an alignment accuracy; (2) variation in dimension among the contact holes; and (3) dimensions of insulating films (i.e., the sidewall 10 or 60 and the interlayer insulating film 14) interposed between the gate electrodes and the contact plugs which ensure insulation therebetween. Hence, when a self-aligned process can not be utilized for formation of the contact holes 115, 165, i.e., when the contact holes 115, 165 can not be self-aligned to the gate electrodes during formation thereof, the conventional method hardly allows reduction in dimensions of the memory formation region and the logic formation region, resulting in making it difficult to miniaturize a semiconductor device.

### SUMMARY OF THE INVENTION

It is an object of the present invention to provide a technique for making it possible to miniaturize a semiconductor device having a memory device and a logic device on one semiconductor substrate, even when a self-aligned process can not be utilized for formation of contact holes, i.e., when contact holes can not be self-aligned to gate electrodes during formation thereof.

According to the present invention, a method of manufacturing a semiconductor device includes the following steps (a) through (f). The step (a) is to prepare a semiconductor substrate having a first region where a memory device is to be formed and a second region where a logic device is to be formed. The semiconductor substrate has a top face on which a first gate structure including a first gate electrode is formed in a portion thereof included in the first region and a second gate structure including a second gate electrode is formed in a portion thereof included in the second region. The step (b) is to form an insulating layer which covers the first and second gate structures on the semiconductor substrate. The step (c) is to form first and second contact holes in portions of the insulating layer included in the first and second regions, respectively, so as to be located beside the first and second gate electrodes, respectively, by etching the insulating layer. The step (d) is to form an insulating film on a side face of each of the first and second contact holes. The step (e) is to form first and second contact plugs filling the first and second contact plugs, respectively, after the step (d). The step (f) is to form a capacitor which is in contact with the first contact plug.

The insulating film is formed on a side face of each of the first and second contact holes, and thereafter, the first and second contact plugs filling the first and second contact holes, respectively, are formed. Accordingly, the insulating film is provided between the first gate electrode and the first contact plug and between the second gate electrode and the second contact plug. As such, by setting a thickness of the insulating film so as to ensure insulation between each of the gate electrodes and each of the contact plugs, it is possible to exclude insulation between each of the gate electrodes and each of the contact plugs, from parameters to take into account in determining a design value of a distance between each of the contact holes and each of the gate electrodes. This makes it possible to reduce a design value of the distance between each of the contact holes and each of the gate electrodes even when a self-aligned process can not be utilized for formation of the contact holes, i.e., when the contact holes can not be self-aligned to the gate electrodes during formation thereof. Thus, the manufacturing method according to the present invention allows for miniaturization of a semiconductor device.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 through 10 are sectional views for illustrating a method of manufacturing a semiconductor device according to a first preferred embodiment of the present invention, in order of occurrence of respective steps.

FIGS. 11 through 20 are sectional views for illustrating a method of manufacturing a semiconductor device according to a second preferred embodiment of the present invention, in order of occurrence of respective steps.

FIGS. 21 through 25 are sectional views for illustrating a method of manufacturing a semiconductor device according to a third preferred embodiment of the present invention, in order of occurrence of respective steps.

FIGS. 26 through 38 are sectional views for illustrating a conventional method of manufacturing a semiconductor device, in order of occurrence of respective steps.

### DESCRIPTION OF THE PREFERRED EMBODIMENTS

Preferred Embodiments

First Preferred Embodiment

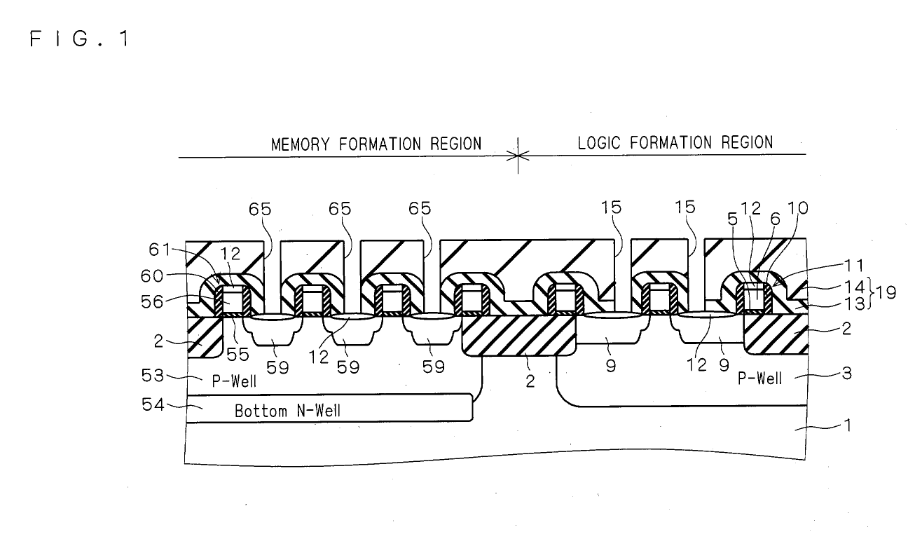

FIGS. 1 through 10 are sectional views for illustrating a method of manufacturing a semiconductor device according to a first preferred embodiment of the present invention, in order of occurrence of respective steps. According to the first preferred embodiment, a semiconductor device to be manufactured is a semiconductor device in which a memory device and a logic device are provided on one semiconductor substrate and a DRAM including a memory cell having a CUB structure and a dual gate salicide CMOS transistor, for example, are employed as the memory device and the logic device, respectively. Below, the method of manufacturing a semiconductor device according to the first preferred embodiment will be described with reference to FIGS. 1 through 10.

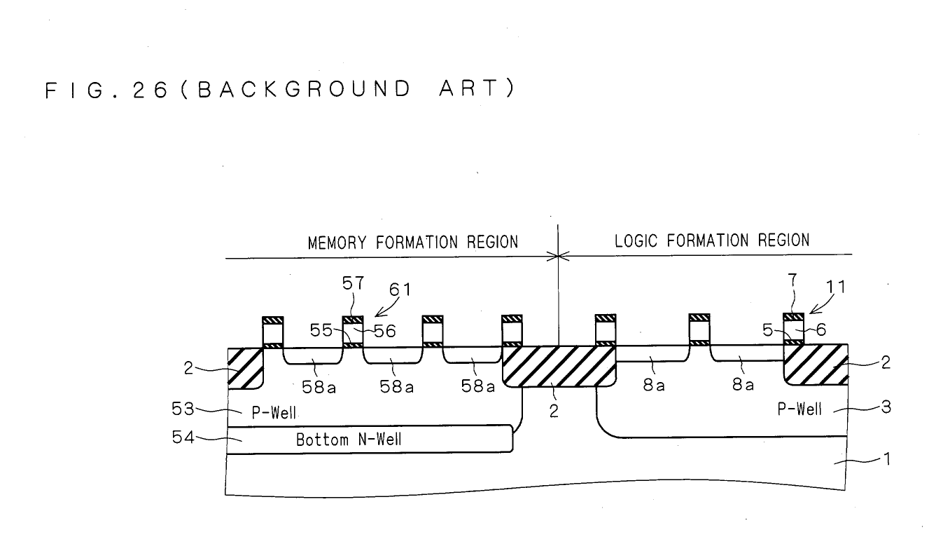

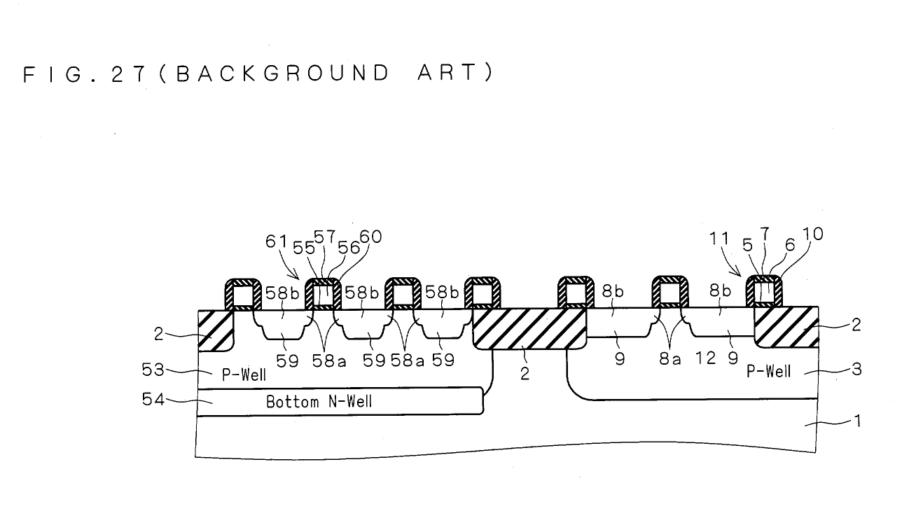

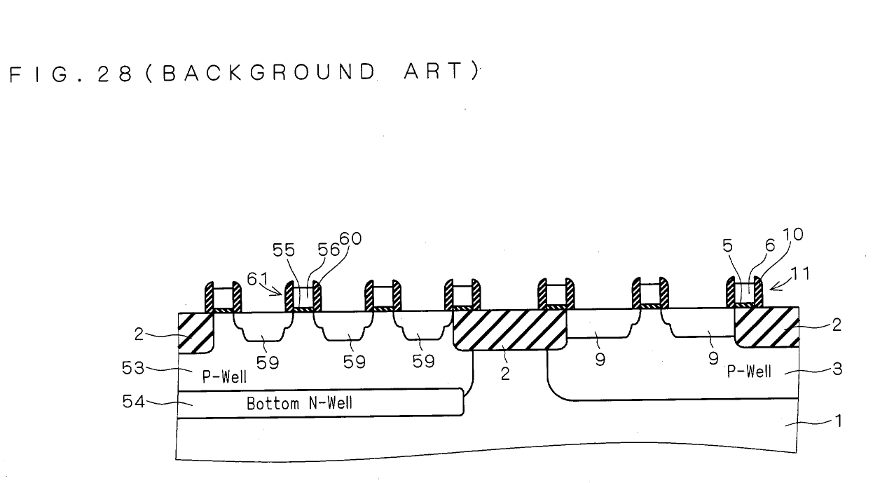

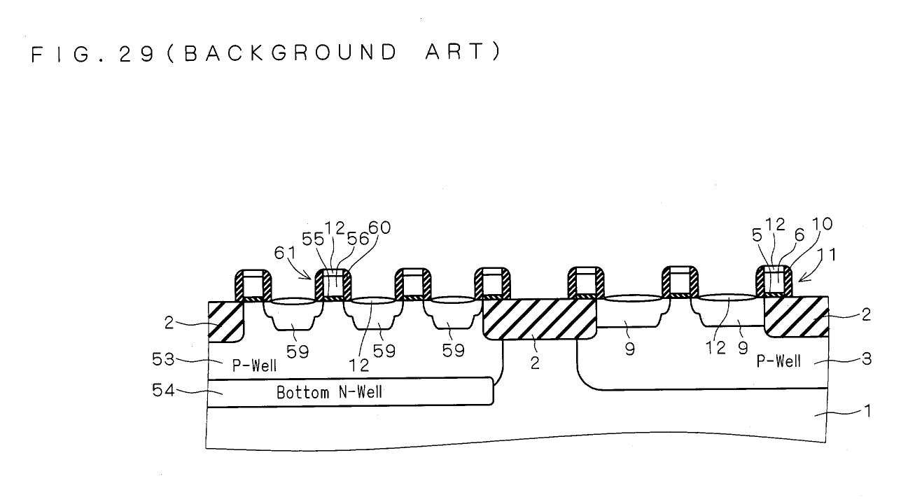

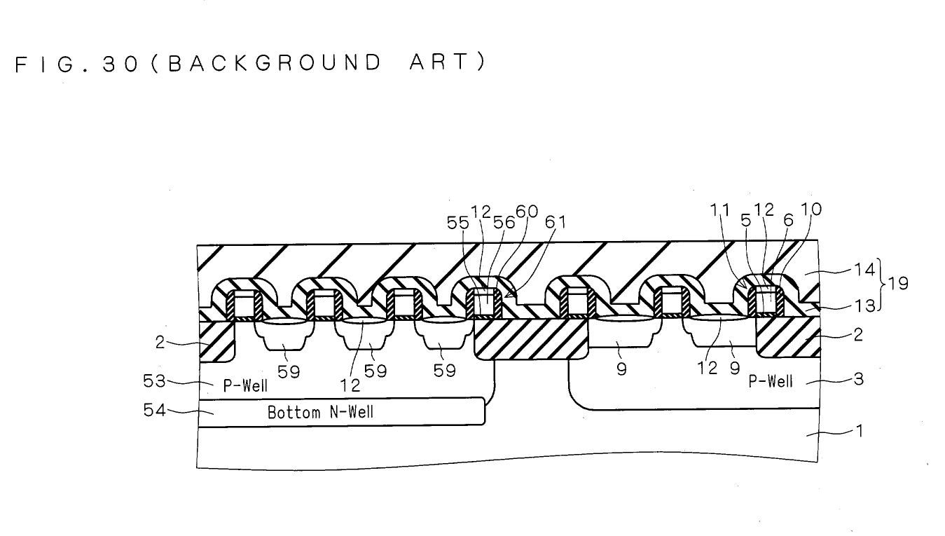

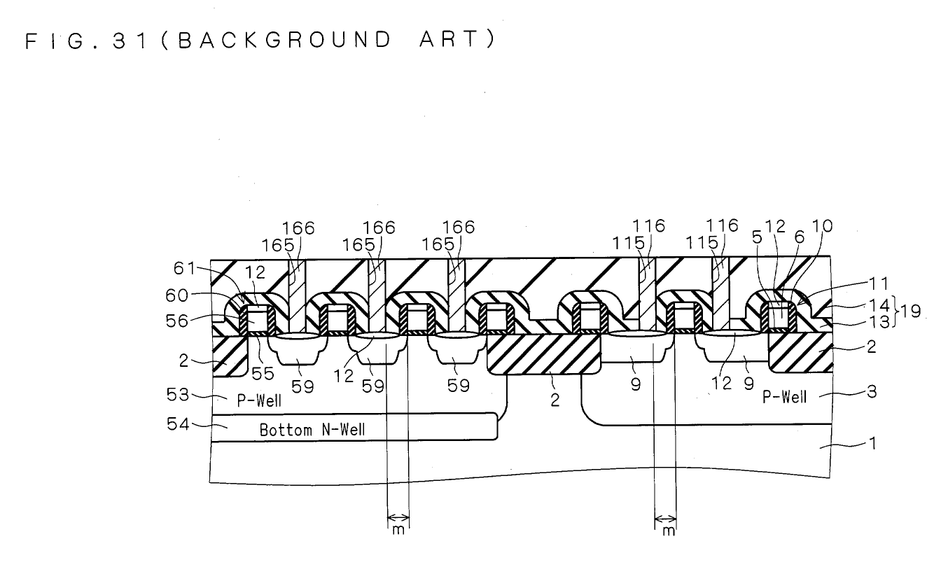

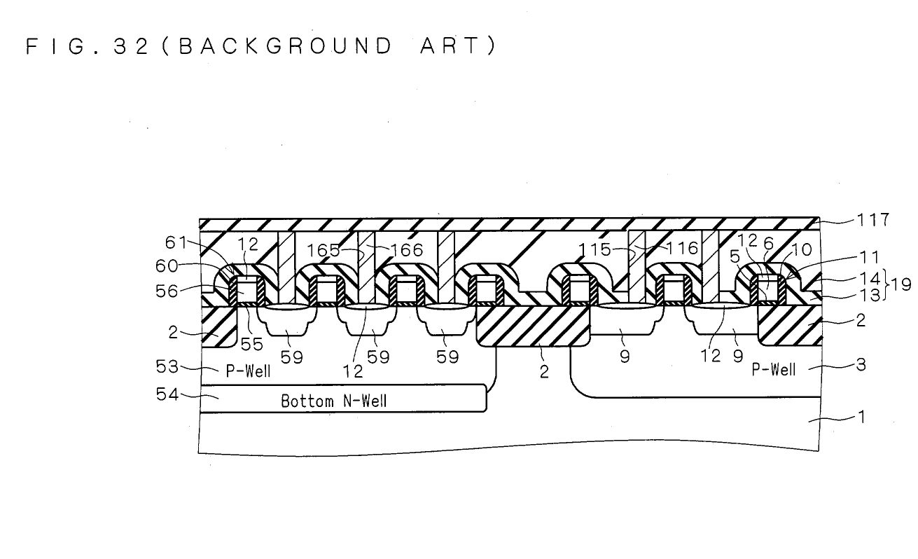

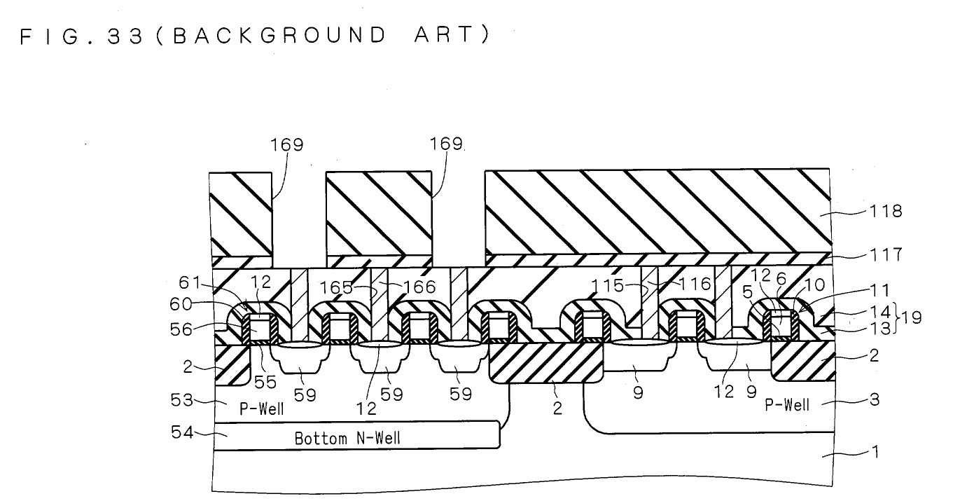

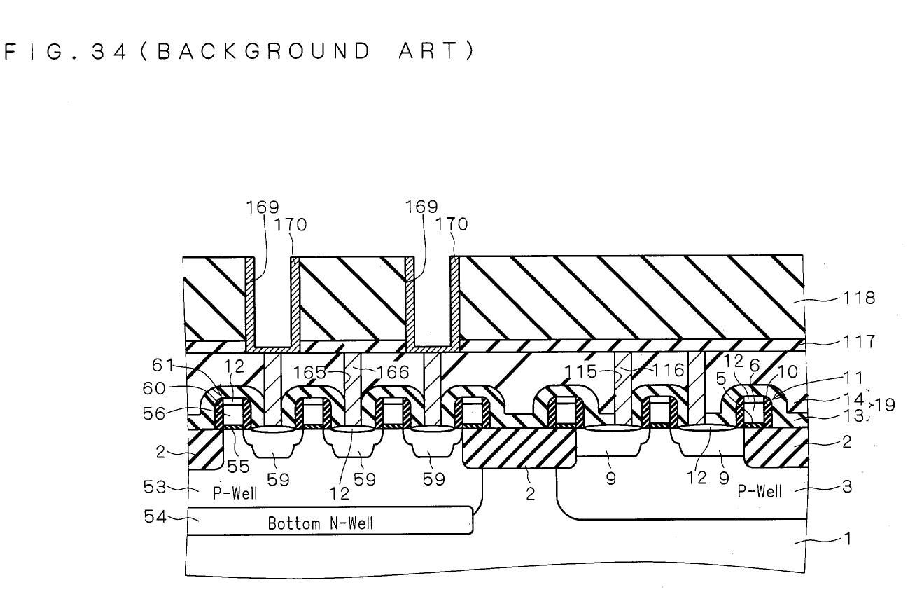

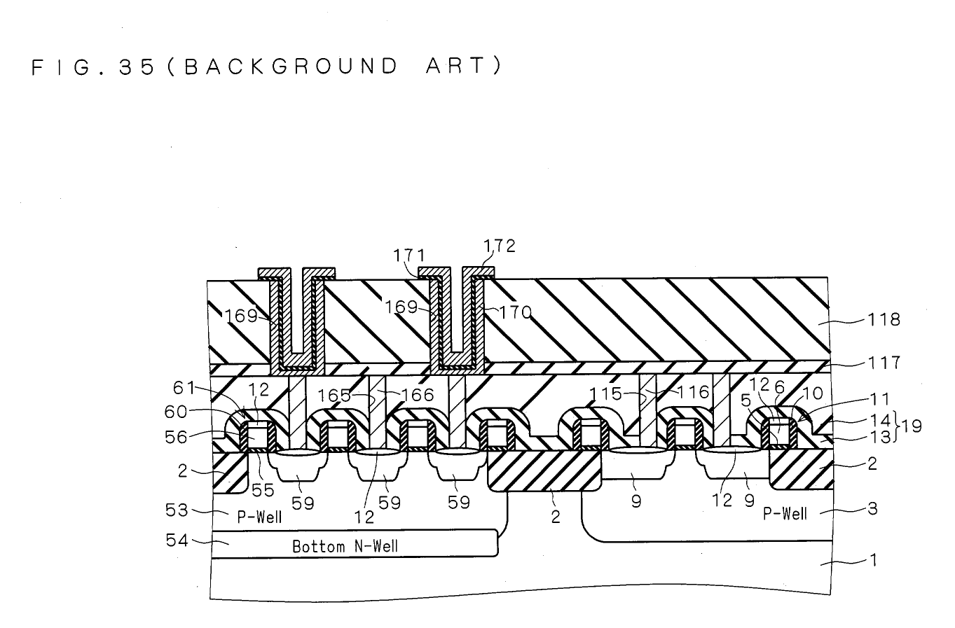

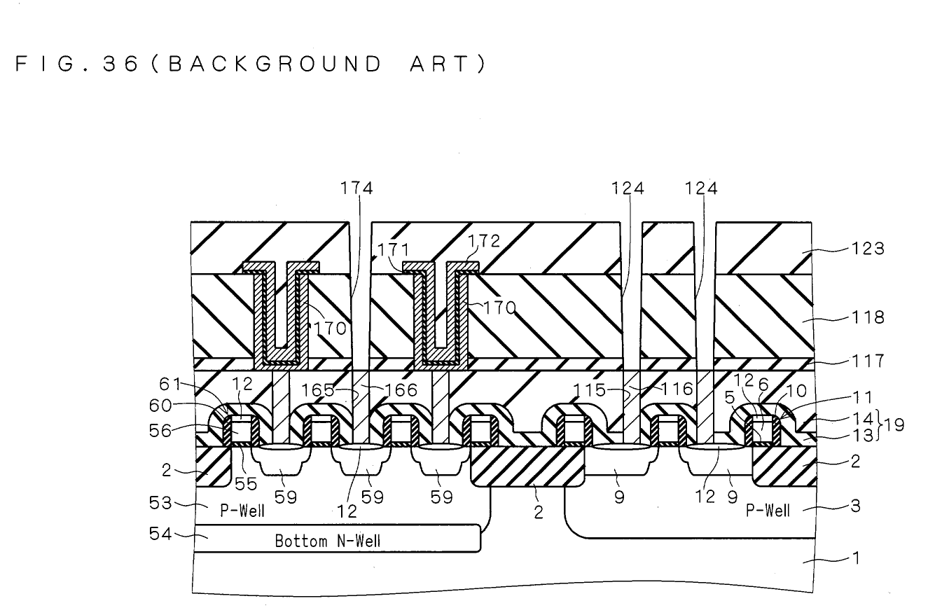

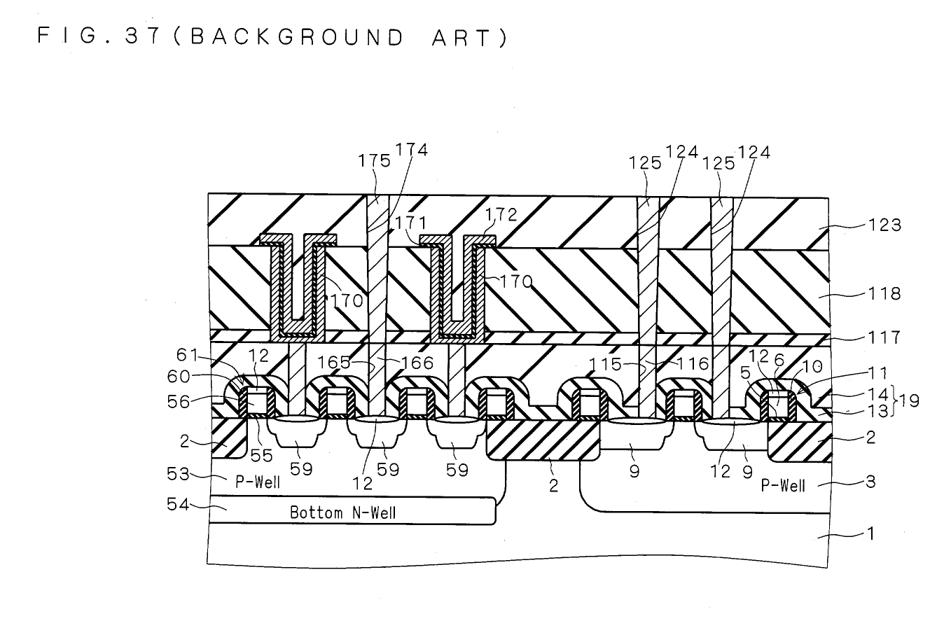

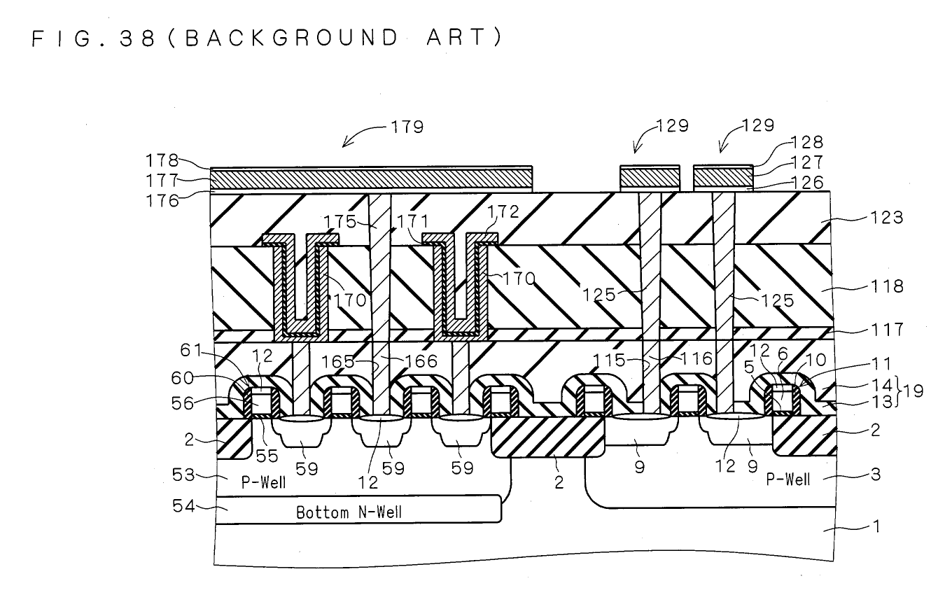

First, the steps described above with reference to FIGS. 26 through 30 are carried out. As a result, the structure illustrated in FIG. 30 is obtained.

Next, referring to FIG. 1, contact holes 65 reaching the cobalt silicide films 12 on the portion of the semiconductor substrate 1 included in the memory formation region, and contact holes 15 reaching the cobalt silicide films 12 on the portion of the semiconductor substrate 1 included in the logic formation region, are formed in the insulating layer 19. More specifically, first, a photoresist (not illustrated) having a predetermined pattern of openings is formed on the interlayer insulating film 14 of the insulating layer 19 by a photolithography process. Then, the interlayer insulating film 14 is etched to be partially removed using the photoresist and the stopper layer 13 as a mask and an etch stop, respectively. For this etching process, anisotropic dry etching using an mixed gas of C₅F₈, O₂ and Ar is employed.

Then, the photoresist is removed, and subsequently exposed portions of the stopper layer 13 are etched to be removed. For this etching process, anisotropic dry etching using a mixed gas of CHF₃, O₂ and Ar is employed. As a result, the contact holes 15 located beside the gate electrodes 6 and above the source/drain regions 9 are formed in portions of the insulating layer 19 included in the logic formation region, and the contact holes 65 located beside the gate electrodes 56 and above the source/drain regions 59 are formed in portions of the insulating layer 19 included in the memory formation region. Further, simultaneously with formation of the contact holes 15, 65, contact holes reaching the cobalt silicide films 12 on the gate electrodes 6, 56 are formed in the insulating layer 19, illustration of which is omitted in the drawings.

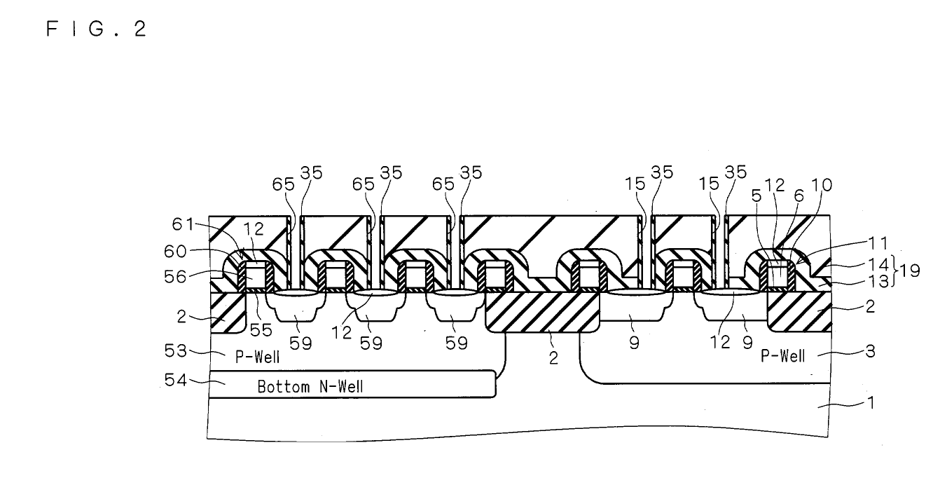

Next, an insulating film made of silicon nitride, for example, is formed on an entire surface of the resultant structure, and then is anisotropically etched from a top face thereof. As a result, an insulating film 35 made of silicon nitride, for example, is formed on each side face of the contact holes 15, 65 and the contact holes (not illustrated) located above the gate electrodes 6, 56, as illustrated in FIG. 2.

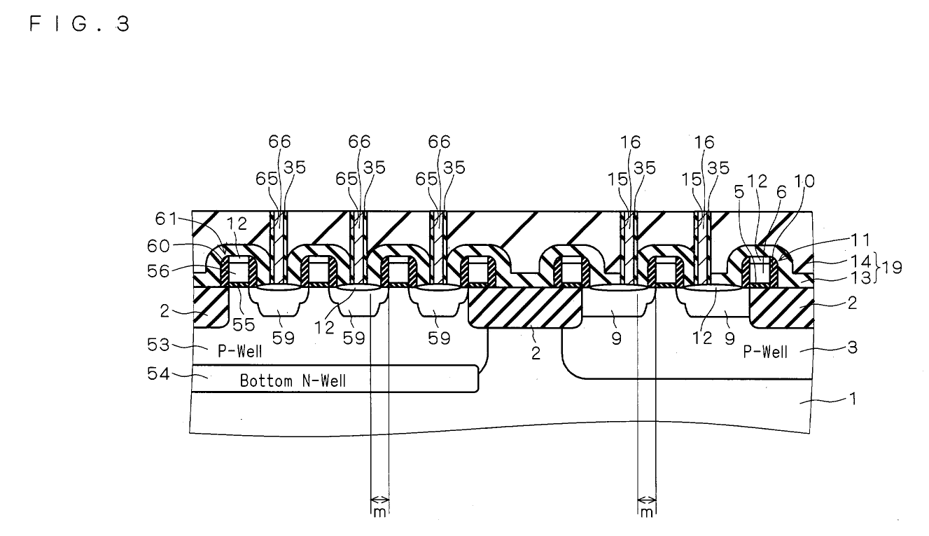

Next, referring to FIG. 3, contact plugs 16 filling the contact holes 15 and contact plugs 66 filling the contact holes 65 are formed. The contact plugs 16, each of which has a top face exposed from the interlayer insulating film 14 of the insulating layer 19, are electrically connected to the portion of the semiconductor substrate 1 included in the logic formation region via the cobalt silicide films 12. The contact plugs 66, each of which has a top face exposed from the interlayer insulating film 14, are electrically connected to the portion of the semiconductor substrate 1 included in the memory formation region via the cobalt silicide films 12. Below, formation of the contact plugs 16, 66 will be described in detail.

First, a stacked film of a barrier metal layer made of titanium nitride or the like and a high melting point metal layer made of titanium, tungsten or the like is formed on an entire surface of the resultant structure such that the barrier metal layer is located under the high melting point metal layer. Then, portions of the stacked film located on the insulating layer 19 are removed by a CMP process. As a result, the contact plugs 16 each composed of a barrier metal layer and a high melting point metal layer are formed to fill the contact holes 15, respectively, and also the contact plugs 66 each composed of a barrier metal layer and a high melting point metal layer are formed to fill the contact holes 65, respectively. Thus, the source/drain regions 59 and the contact plugs 66 are electrically connected to each other, as well as the source/drain regions 9 and the contact plugs 16 are electrically connected to each other. Further, simultaneously with formation of the contact plugs 16, 66, contact plugs filling the contact holes located above the gate electrodes 6, 56 are formed. Those contact plugs are provided in the insulating layer 19 and are electrically connected to the gate electrodes 6, 56 via the cobalt silicide films 12.

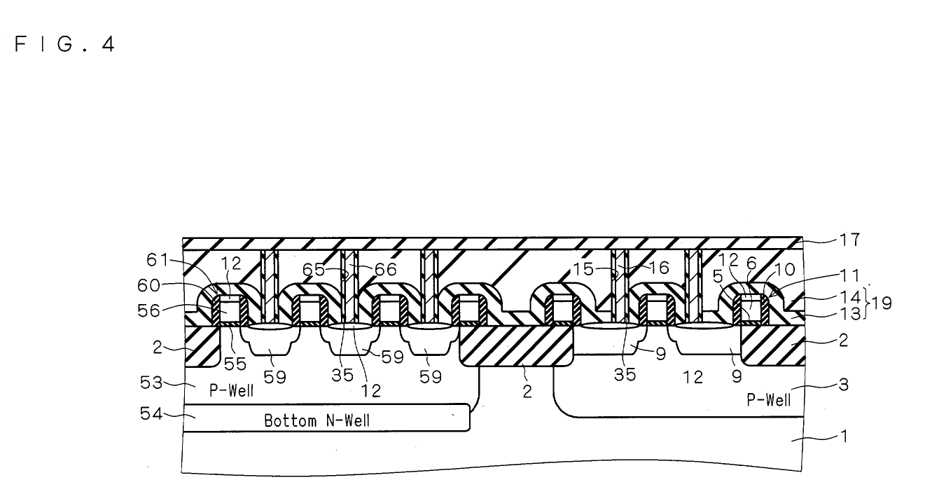

Next, referring to FIG. 4, a stopper layer 17 made of silicon nitride, for example, is formed on an entire surface of the resultant structure, i.e., on the interlayer insulating film 14 and the contact plugs 16, 66 in the insulating layer 19.

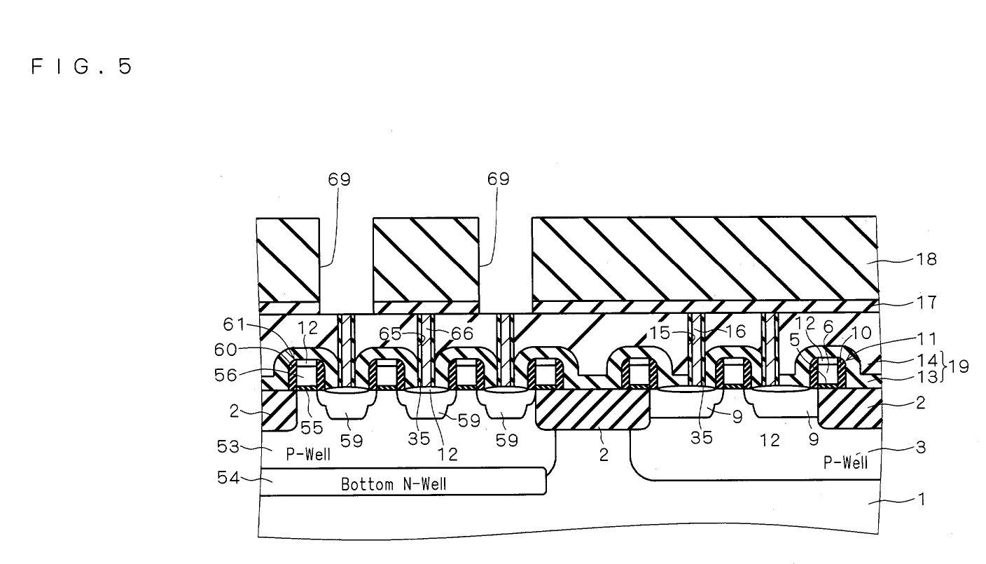

Next, referring to FIG. 5, an interlayer insulating film 18 is formed on the stopper layer 17. A BPTEOS film is employed as the interlayer insulating film 18, for example. Subsequently, a photoresist (not illustrated) having a predetermined pattern of openings is formed on the interlayer insulating film 18. Then, the interlayer insulating film 18 is etched to be partially removed using the photoresist and the stopper layer 17 as a mask and an etch stop, respectively. For this etching process, anisotropic dry etching using a mixed gas of C₅F₈, O₂ and Ar is employed.

Thereafter, the photoresist is removed, and exposed portions of the stopper layer 17 are etched to be removed. For this etching process, anisotropic dry etching using a mixed gas of CHF₃, O₂ and Ar is employed. As a result, openings 69 by which some of the contact plugs 66 each being electrically connected to one of two adjacent source/drain regions 59 are exposed are formed in the interlayer insulating film 18 and the stopper layer 17.

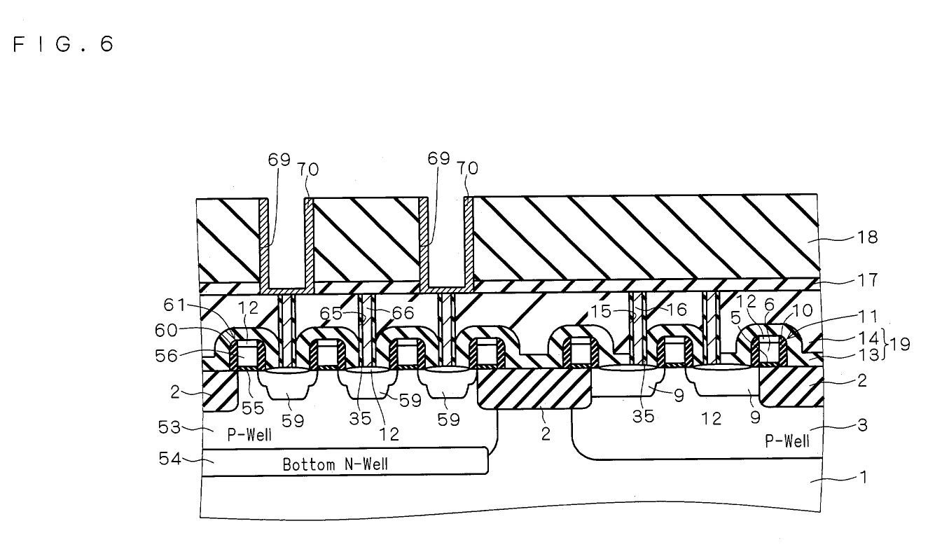

Next, capacitors of the memory cell of the DRAM which are in contact with the exposed ones of the contact plugs 66 are formed in the openings 69. More specifically, a metal film containing a high melting point metal such as ruthenium is formed on an entire surface of the resultant structure. Then, portions of the metal film located on a top face of the interlayer insulating film 18 are removed by anisotropic dry etching with the openings 69 being covered with a photoresist (not illustrated). As a result, lower electrodes 70 of the capacitors each containing a high melting point metal such as ruthenium are formed in the openings 69 as illustrated in FIG. 6. Additionally, instead of anisotropic dry etching described above, a CMP process may alternatively be employed for removing the portions of the metal film located on the top face of the interlayer insulating film 18.

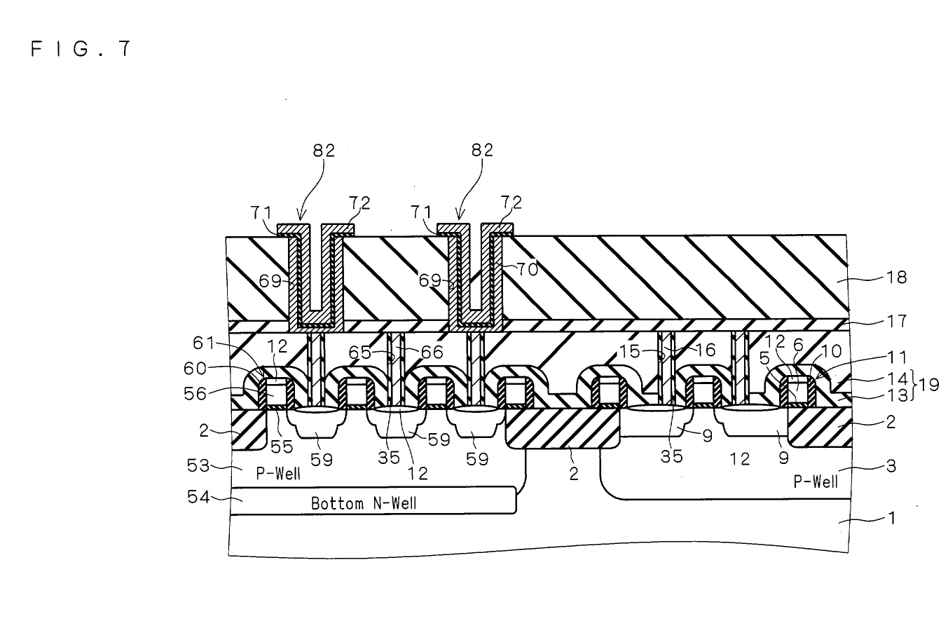

Next, an insulating film made of tantalum pentoxide, and subsequently, a metal film containing a high melting point metal such as ruthenium are formed on an entire surface of the resultant structure. Then, the formed insulating film and the formed metal film are patterned using a photoresist. As a result, dielectric films 71 each made of tantalum pentoxide and upper electrodes 72 each containing a high melting point metal such as ruthenium are formed, to complete capacitors 82 in the openings 69 as illustrated in FIG. 7.

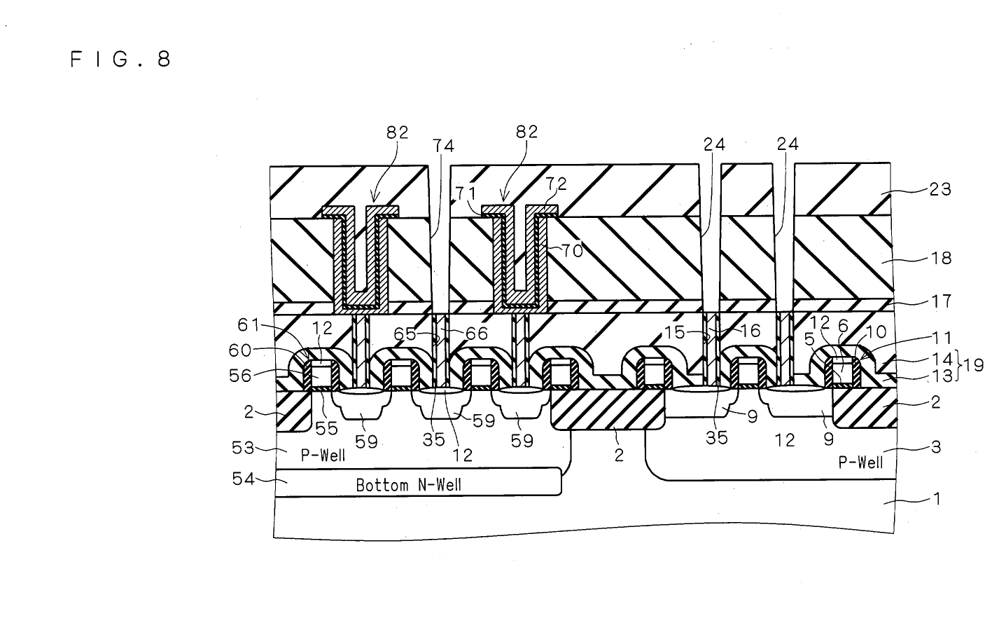

Next, referring to FIG. 8, an interlayer insulating film 23 made of TEOS, for example, is formed on an entire surface of the resultant structure, and then is planarized by a CMP process. Thus, the interlayer insulating film 23 covering the capacitors 82 is formed on the interlayer insulating film 18. Thereafter, contact holes 24 and contact holes 74 are formed in the interlayer insulating films 18 and 23 and the stopper layer 17. The contact holes 24 extend from a top face of the interlayer insulating film 23, to reach the contact plugs 16. The contact holes 74 extend from the top face of the interlayer insulating film 23, to reach some of the contact plugs 66 which are not in contact with the capacitors 82.

For formation of the contact holes 24 and 74, first, a photoresist (not illustrated) having a predetermined pattern of openings is formed on the interlayer insulating film 23. Then, the interlayer insulating films 18 and 23 are etched to be partially removed using the photoresist and the stopper layer 17 as a mask and an etch stop, respectively. For this etching process, anisotropic dry etching using a mixed gas of C₅F₈, O₂ and Ar is employed. Then, the photoresist is removed, and subsequently exposed portions of the stopper layer 17 are etched to be removed. For this etching process, anisotropic dry etching using a mixed gas of CHF₃, O₂ and Ar is employed. Further, simultaneously with formation of the contact holes 24 and 74, contact holes extending from the top face of the interlayer insulating film 23 to reach the upper electrodes 72 are formed in the interlayer insulating film 23, illustration of which is omitted in the drawings.

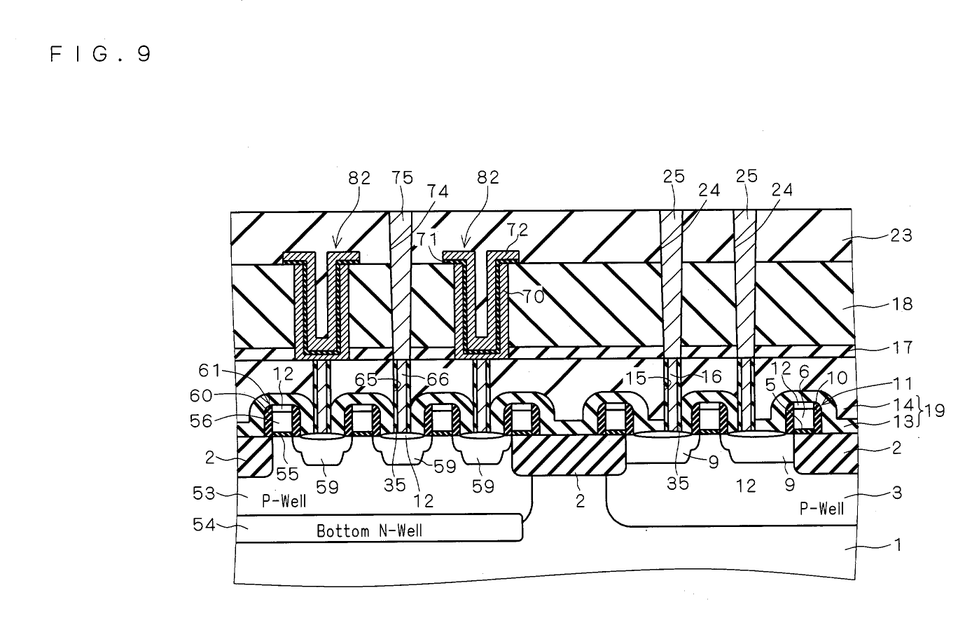

Next, a stacked film of a barrier metal layer made of titanium nitride or the like and a high melting point metal layer made of titanium, tungsten or the like is formed on an entire surface of the resultant structure such that the barrier metal layer is located under the high melting point metal layer. Then, portions of the stacked film located on the top face of the interlayer insulating film 23 is removed by a CMP process. As a result, contact plugs 25 each composed of a barrier metal layer and a high melting point metal layer are formed to fill the contact holes 24, respectively, and contact plugs 75 each composed of a barrier metal layer and a high melting point metal layer are formed to fill the contact holes 74, respectively, as illustrated in FIG. 9.

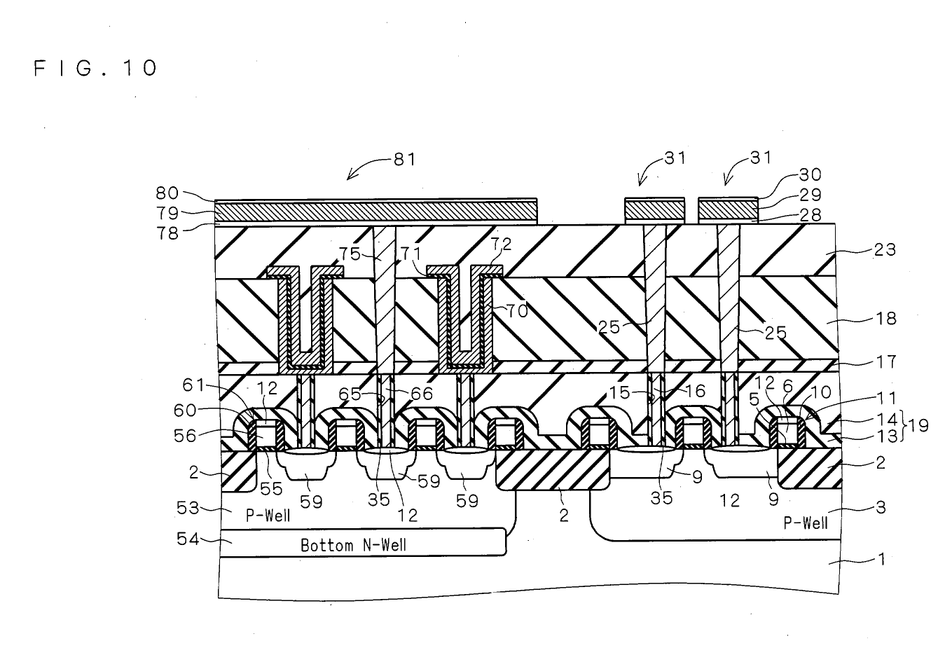

Next, referring to FIG. 10, interconnects 31 are formed in contact with the contact plugs 25 and interconnects 81 are formed in contact with the contact plugs 75 on the interlayer insulating film 23. Each of the interconnects 31 is formed of an aluminum interconnect 29 vertically interposed between titanium nitride layers 28 and 30. Analogously to the interconnects 31, each of the interconnects 81 is formed of an aluminum interconnect 79 vertically interposed between titanium nitride layers 78 and 80. Additionally, the interconnects 81 function as bit lines of the memory cell of the DRAM.

By the foregoing steps, the memory device and the logic device are formed in the memory formation region and the logic formation region, respectively.

As described above, in accordance with the method of manufacturing a semiconductor device of the first preferred embodiment, the insulating film 35 is formed on each side face of the contact holes 15, 65 (see FIG. 2), and after that, the contact plugs 16 filling the contact holes 15 and the contact plugs 66 filling the contact holes 65 are formed (see FIG. 3).

Accordingly, the insulating film 35 is provided between each of the contact holes 15 and each of the gate electrodes 6, and between each of the contact holes 65 and each of the gate electrodes 56. Hence, by setting a thickness of the insulating film 35 so as to ensure insulation between each of the gate electrodes 6 and each of the contact plugs 16, it is possible to exclude one parameter from the three parameters to take into account which are noted in the Background Art section, in determining a design value of the distance m (see FIG. 3) between each of the contact holes 15 and each of the gate electrodes 6. In the manufacturing method according to the first preferred embodiment, only the two parameters of (1) alignment accuracy and (2) variation in dimension among the contact holes should be taken into account, and there is no need to take into account the parameter of (3) dimensions of insulating films interposed between each of the gate electrodes and each of the contact plugs which ensure insulation therebetween. In other words, there is no need to take into account insulation between each of the gate electrodes 6 and each of the contact plugs 16 in determining a design value of the distance m between each of the contact holes 15 and each of the gate electrodes 6.

For the same reasons as noted above, by setting a thickness of the insulating film 35 so as to ensure insulation between each of the gate electrodes 56 and each of the contact plugs 66, it is possible to determine a design value of the distance m between each of the gate electrodes 56 and each of the contact holes 65 without having to take into account the parameter of (3) dimensions of insulating films interposed between each of the gate electrodes and each of the contact plugs which ensure insulation therebetween.

Therefore, the manufacturing method according to the firs preferred embodiment of the present invention makes it possible to reduce a design value of the distance m between each of the contact holes and each of the gate electrodes, as compared to the conventional method, even when a self-aligned process can not be utilized for formation of the contact holes, i.e., when the contact holes can not be self-aligned to the gate electrodes during formation thereof. Hence, respective dimensions of the memory formation region and the logic formation region can be reduced. Thus, the manufacturing method according to the first preferred embodiment allows for formation of a semiconductor device which is more compact than a semiconductor device manufactured by the conventional method.

Second Preferred Embodiment

In accordance with the above-described method of manufacturing a semiconductor device of the first preferred embodiment, formation of the openings 69 (see FIG. 5) or the contact holes, 15, 65, 24 and 74 (see FIGS. 1 and 8) is achieved by etching the interlayer insulating films 14 and 18 using each of the stopper layers 13 and 17 as an etch stop, and subsequently etching the stopper layers 13 and 17. During the process of etching the interlayer insulating films 14 and 18, fluorocarbon-based (CxFy) deposits (deposit films) are provided on a top face of each of the stopper layers 13 and 17 because of the use of the mixed gas described in the first preferred embodiment. The provision of the deposit films serves to increase an etch selectivity of the interlayer insulating films 14 and 18 relative to the stopper layers 13 and 17 for the process of etching the films 14 and 18.

However, the provision of the deposit films on the stopper layers 13 and 17 turns to be detrimental to the subsequent step of etching the stopper layers 13 and 17. Specifically, it is impossible to successfully etch the stopper layers 13 and 17 with the deposit films kept provided on the stopper layers 13 and 17 because the deposit films each function as a mask. In view of this, in the method of first preferred embodiment, the step of removing the photoresist by which also the deposit films are removed is performed prior to etching the stopper layers 13 and 17.

As described, the method of manufacturing a semiconductor device according to the first preferred embodiment requires the steps of etching the interlayer insulating films 14 and 18 and the stopper layers 13 and 17, and further requires the step of removing the photoresist between the two etching steps, in forming the openings 69 or the contact holes 15, 65, 24 and 74. For this reason, it is necessary to switch a manufacturing system from an etching system to an ashing system, and from an ashing system to an etching system, in forming the openings 69 or the contact holes 15, 65, 24 and 74. This increases time required for entire manufacture of a semiconductor device.

In view of the above-noted disadvantage, methods of manufacturing a semiconductor device according to second and third preferred embodiments provide for reduction in time required for manufacturing a semiconductor device.

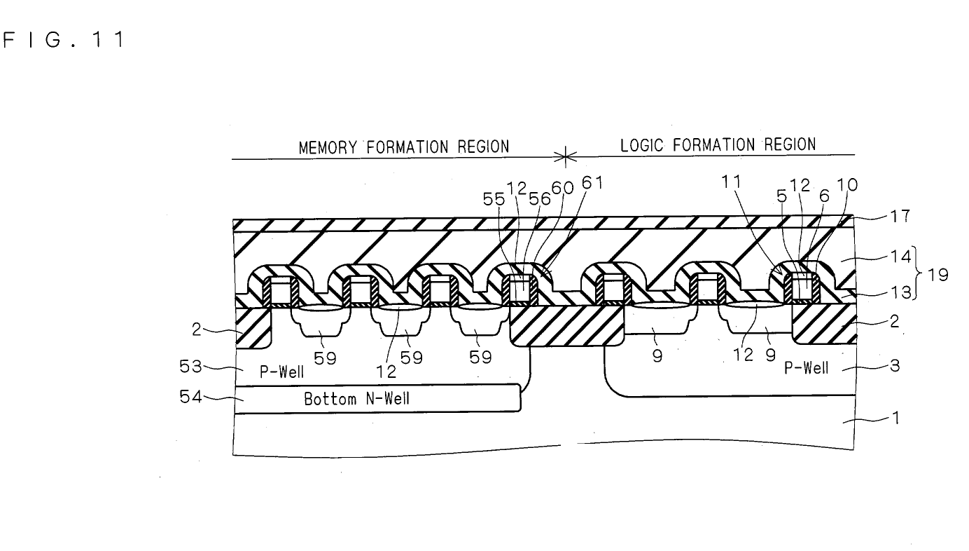

FIGS. 11 through 20 are sectional views for illustrating the method of manufacturing a semiconductor device according to the second preferred embodiment of the present invention, in order of occurrence of respective steps. According to the second preferred embodiment, a semiconductor device to be manufactured is a semiconductor device in which a memory device and a logic device are provided on one semiconductor substrate and a DRAM including a memory cell having a CUB structure and a dual gate salicide CMOS transistor, for example, are employed as the memory device and the logic device, respectively. Below, the method of manufacturing a semiconductor device according to the second preferred embodiment will be described with reference to FIGS. 11 through 20.

First, the steps described above with reference to FIGS. 26 through 30 are carried out. As a result, the structure illustrated in FIG. 30 is obtained.

Subsequently, the stopper layer 17 is formed on the insulating layer 19, in particular, on the interlayer insulating film 14, as illustrated in FIG. 11.

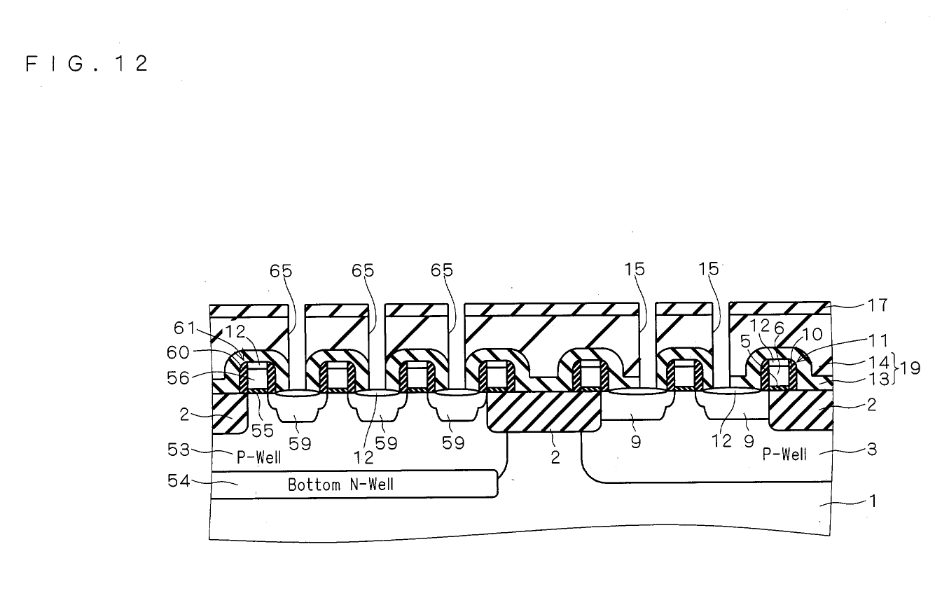

Next, referring to FIG. 12, the contact holes 65 reaching the cobalt silicide films 12 on the portion of the semiconductor substrate 1 included in the memory formation region, and the contact holes 15 reaching the cobalt silicide films 12 on the portion of the semiconductor substrate 1 included in the logic formation region, are formed in the insulating layer 19 and the stopper layer 17. More specifically, first, a photoresist (not illustrated) having a predetermined pattern of openings is formed on the stopper layer 17 by a photolithography process. Then, the stopper layer 17 is etched to be partially removed using the photoresist as a mask. For this etching process, anisotropic dry etching using an mixed gas of CHF₃, O₂ and Ar, for example, is employed.

Then, the interlayer insulating film 14 is etched again using the photoresist remaining on the stopper layer 17 as a mask after altering conditions for etching such as a kind of a gas to be used. For this etching process, the stopper layer 13 functions as an etch stop, and a mixed gas of C₅F₈, O₂ and Ar, for example, is employed.

Thereafter, the photoresist is removed, and subsequently etching is carried out on an entire surface of the resultant structure to remove exposed portions of the stopper layer 13. For this etching process, anisotropic dry etching using a mixed gas of CHF₃, O₂ and Ar is employed. As a result, the contact holes 15 located beside the gate electrodes 6 and above the source/drain regions 9 are formed in portions of the insulating layer 19 and portions of the stopper layer 17 each included in the logic formation region. Also, the contact holes 65 located beside the gate electrodes 56 and above the source/drain regions 59 are formed in portions of the insulating layer 19 and portions of the stopper layer 17 each included in the memory formation region. Further, simultaneously with formation of the contact holes 15, 65, contact holes reaching the cobalt silicide films 12 on the gate electrodes 6, 56 are formed in the insulating layer 19 and the stopper layer 17, illustration of which is omitted in the drawings. Meanwhile, as the removal of the exposed portions of the stopper layer 13 is achieved by etching the entire surface of the resultant structure, also the stopper layer 17 is subjected to etching. In this connection, a thickness of the stopper layer 17 has previously been controlled so as to allow the stopper layer 17 to have a predetermined thickness after etching (removing) the stopper layer 13.

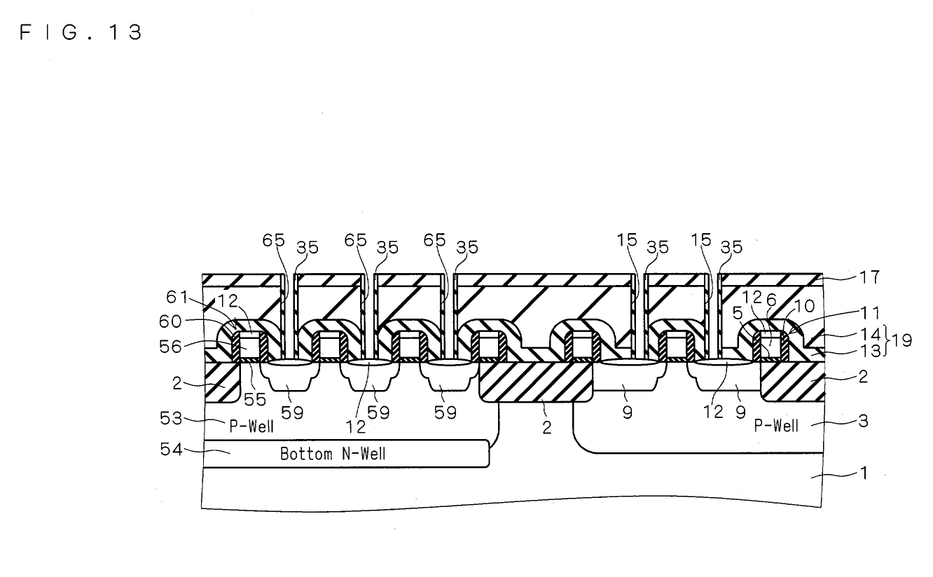

Next, an insulating film made of silicon nitride, for example, is formed on an entire surface of the resultant structure, and then is anisotropically etched from a top face thereof. As a result, the insulating film 35 is formed on each side face of the contact holes 15, 65 and the contact holes (not illustrated) located above the gate electrodes 6, 56, as illustrated in FIG. 13.

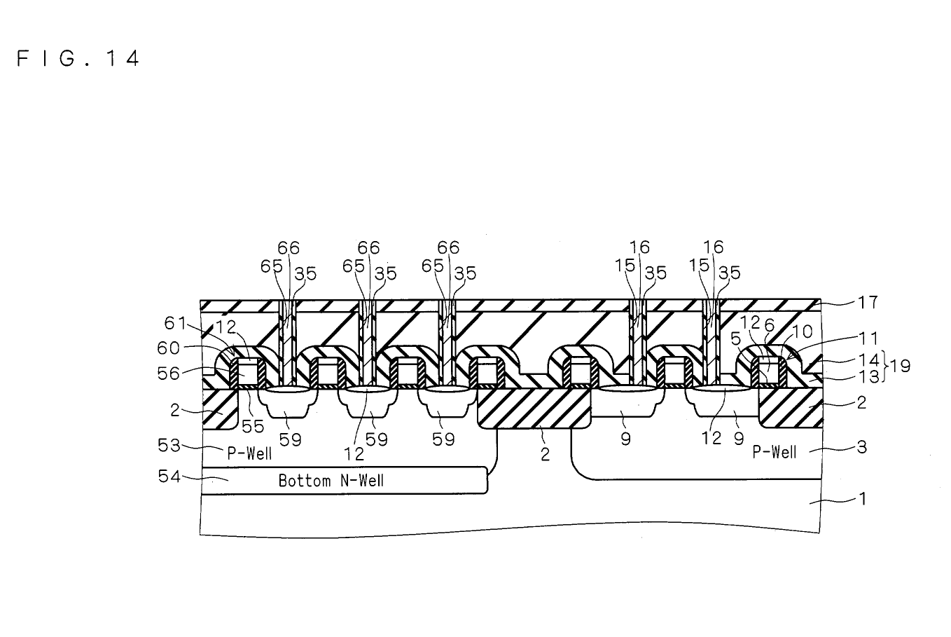

Next, referring to FIG. 14, the contact plugs 16 filling the contact holes 15 and the contact plugs 66 filling the contact holes 65 are formed. The contact plugs 16, each of which has a top face exposed from the stopper layer 17, are electrically connected to the portion of the semiconductor substrate 1 included in the logic formation region via the cobalt silicide films 12. The contact plugs 66, each of which has a top face exposed from the stopper layer 17, are electrically connected to the portion of the semiconductor substrate 1 included in the memory formation region via the cobalt silicide films 12. Below, formation of the contact plugs 16, 66 will be described in detail.

First, a stacked film of a barrier metal layer made of titanium nitride or the like and a high melting point metal layer made of titanium, tungsten or the like is formed on an entire surface of the resultant structure such that the barrier metal layer is located under the high melting point metal layer. Then, portions of the stacked film located on the top face of the stopper layer 17 are removed by a CMP process. As a result, the contact plugs 16 are formed to fill the contact holes 15, respectively, and also the contact plugs 66 are formed to fill the contact holes 65, respectively. Thus, the source/drain regions 59 and the contact plugs 66 are electrically connected to each other, as well as the source/drain regions 9 and the contact plugs 16 are electrically connected to each other. Further, simultaneously with formation of the contact plugs 16, 66, contact plugs filling the contact holes located above the gate electrodes 6, 56 are formed. Those contact holes are provided in the insulating layer 19 and the stopper layer 17 and are electrically connected to the gate electrodes 6, 56 via the cobalt silicide films 12.

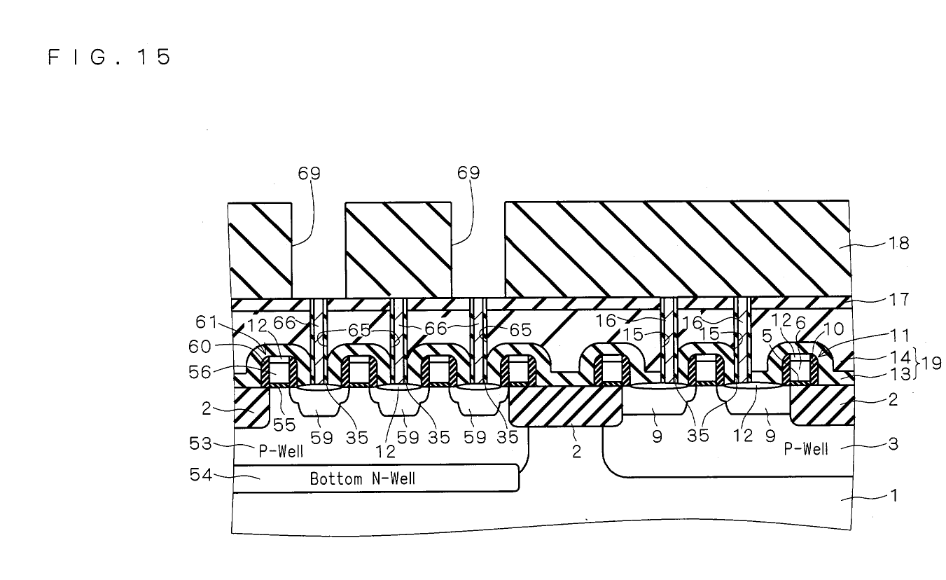

Next, referring to FIG. 15, the interlayer insulating film 18 is formed on an entire surface of the resultant structure, so that the interlayer insulating film 18 is provided on the stopper layer 17 and the contact plugs 16, 66. Then, a photoresist (not illustrated) having a predetermined pattern of the openings is formed on the interlayer insulating film 18. Thereafter, the interlayer insulating film 18 is etched to be partially removed using the photoresist as a mask and using each of the stopper layer 17 and the contact plugs 66 as an etch stop, which is followed by removal of the photoresist. For the process of etching the interlayer insulating film 18, anisotropic dry etching using a mixed gas of C₅F₈, O₂ and Ar is employed. As a result, the openings 69 by which some of the contact plugs 66 each being electrically connected to one of two adjacent source/drain regions 59 are formed in the interlayer insulating film 18.

As generally known, the above described conditions employed for etching the interlayer insulating film 18 provide such a high etch selectivity of the interlayer insulating film 18 relative to the contact plugs 66 as not to allow the contact plugs 66 to be easily etched. Hence, each of the contact plugs 66, as well as the stopper layer 17, can be used as an etch stop which prevents the openings 69 from reaching the gate electrodes 56 or the semiconductor substrate 1.

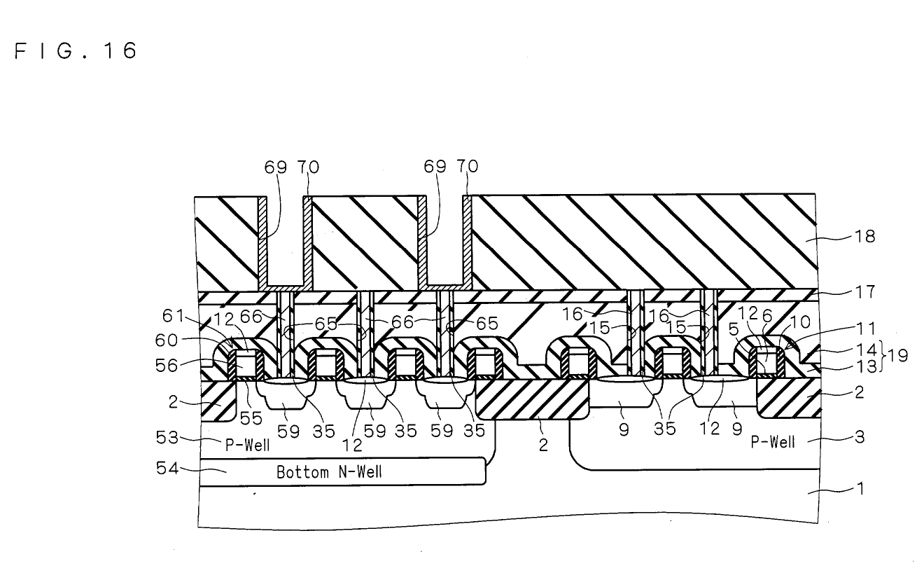

Next, the capacitors 82 of the memory cell of the DRAM which are in contact with the exposed ones of the contact plugs 66 are formed in the openings 69. More specifically, a metal film containing a high melting point metal such as ruthenium is formed on an entire surface of the resultant structure. Then, portions of the metal film located on the top face of the interlayer insulating film 18 are removed by anisotropic dry etching with the openings 69 being covered with a photoresist (not illustrated). As a result, the lower electrodes 70 of the capacitors 82 are formed in the openings 69 as illustrated in FIG. 16. Additionally, instead of anisotropic dry etching described above, a CMP process may alternatively be employed for removing the portions of the metal film located on the top face of the interlayer insulating film 18.

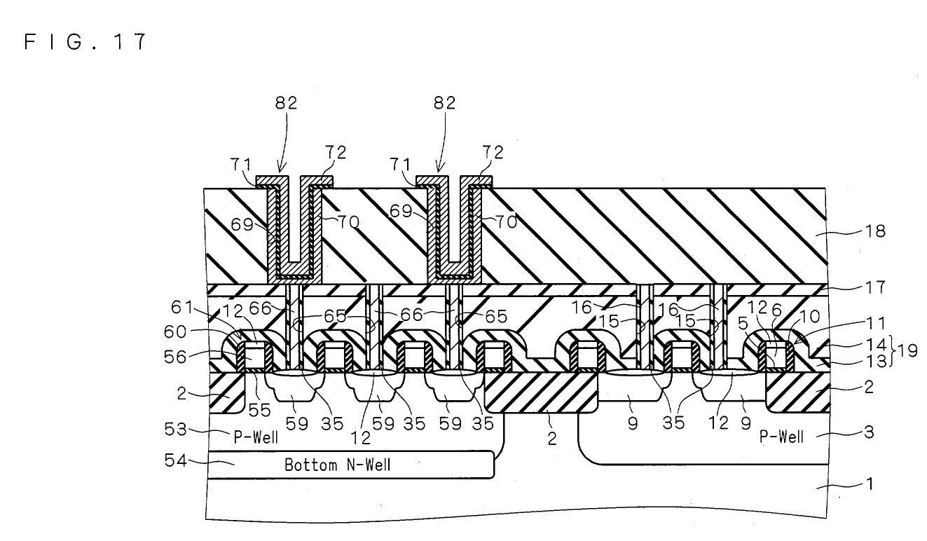

Next, an insulating film made of tantalum pentoxide, and subsequently, a metal film containing a high melting point metal such as ruthenium are formed on an entire surface of the resultant structure. Then, the formed insulating film and the formed metal film are patterned using a photoresist. As a result, the dielectric films 71 and the upper electrodes 72 of the capacitors 82 are formed, to complete the capacitors 82 in the openings 69 as illustrated in FIG. 17.

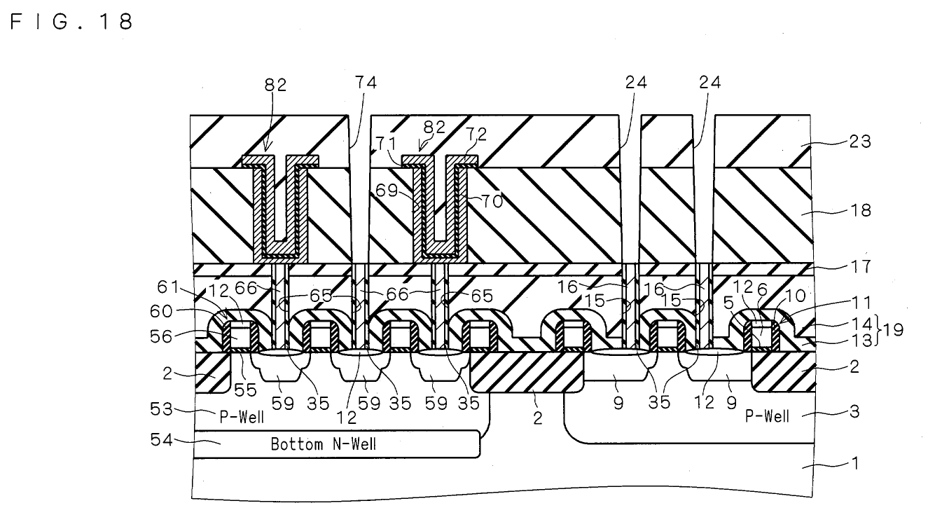

Next, referring to FIG. 18, the interlayer insulating film 23 is formed on an entire surface of the resultant structure, and then is planarized by a CMP process. Thus, the interlayer insulating film 23 covering the capacitors 82 are formed on the interlayer insulating film 18. Thereafter, the contact holes 24 and the contact holes 74 are formed in the interlayer insulating films 18 and 23. More specifically, a photoresist (not illustrated) having a predetermined pattern of openings is formed on the interlayer insulating film 23. Subsequently, the interlayer insulating films 18 and 23 are etched to be partially removed using the photoresist as a mask and using each of the stopper layer 17 and the contact plugs 16, 66 as an etch stop, which is followed by removal of the photoresist. For the process of etching the interlayer insulating films 18 and 23, anisotropic dry etching using a mixed gas of C₅F₈, O₂ and Ar is employed.

Thus, the contact holes 24 extending from the top face of the interlayer insulating film 23 and reaching the contact plugs 16, as well as the contact holes 74 extending from the top face of the interlayer insulating film 23 and reaching some of the contact plugs 66 which are not in contact with the capacitors 82, are formed.

As generally known, the above described conditions employed for etching the interlayer insulating films 18 and 23 provide such a high etch selectivity of the interlayer insulating films 18 and 23 relative to the contact plugs 16, 66 as not to allow the contact plugs 16, 66 to be easily etched. Hence, each of the contact plugs 16, 66, as well as the stopper layer 17, can be used as an etch stop. Further, contact holes extending from the top face of the interlayer insulating film 23 and reaching the upper electrodes 72 are formed in the interlayer insulating film 23, illustration of which is omitted in the drawings.

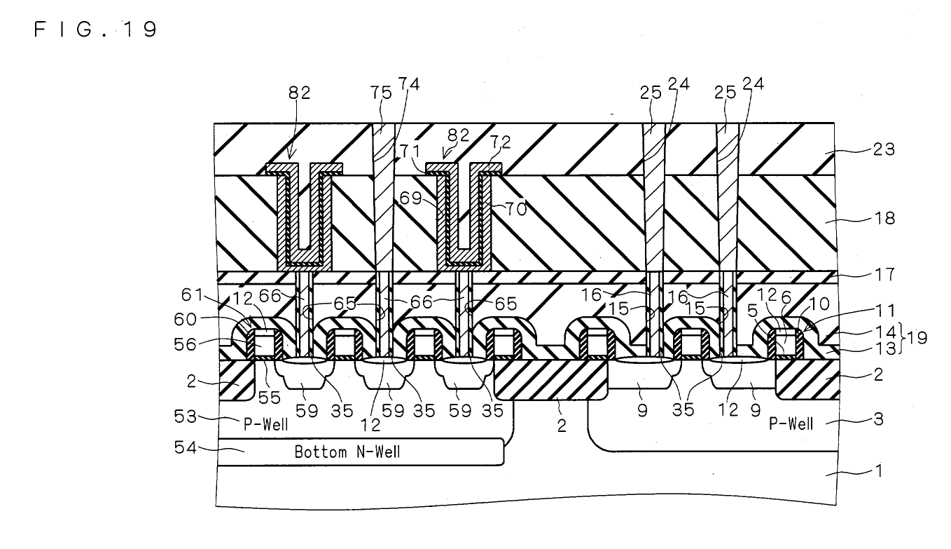

Next, a stacked film of a barrier metal layer made of titanium nitride or the like and a high melting point metal layer made of titanium, tungsten or the like is formed on an entire surface of the resultant structure such that the barrier metal layer is located under the high melting point metal layer. Then, portions of the stacked film located on the top face of the interlayer insulating film 23 are removed by a CMP process. As a result, the contact plugs 25 are formed to fill the contact holes 24, respectively, and the contact plugs 75 are formed to fill the contact holes 74, respectively, as illustrated in FIG. 19.

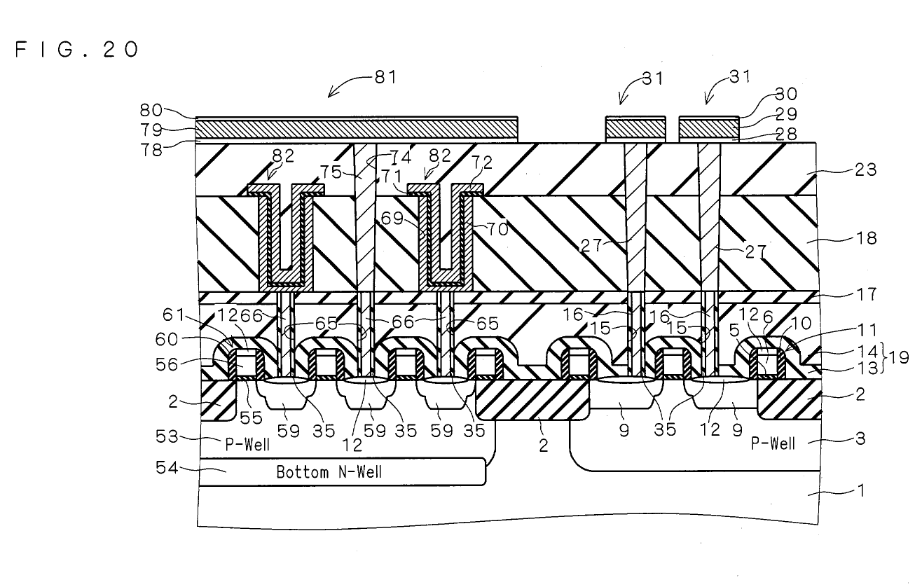

Next, referring to FIG. 20, the interconnects 31 are formed in contact with the contact plugs 25 and the interconnects 81 are formed in contact with the contact plugs 75, on the interlayer insulating film 23.

By the foregoing steps, the memory device and the logic device are formed in the memory formation region and the logic formation region, respectively.

As described above, in accordance with the method of manufacturing a semiconductor device of the second preferred embodiment, the contact plugs 16, 66 are formed in not only the insulating layer 19 but also the stopper layer 17. Accordingly, the stopper layer 17 is not etched during formation of the openings 69 or the contact holes 24, 74. In the method of manufacturing a semiconductor device according to the second preferred embodiment, while it is required that a manufacturing system be switched from an etching system to an ashing system in order to remove the photoresist after etching the interlayer insulating films, there is no need to further switch a manufacturing system from an ashing system to an etching system in forming the openings 69 or the contact holes 24, 74, unlike the manufacturing method according to the first preferred embodiment. Hence, time required for forming the openings 69 or the contact holes 24, 74 can be reduced. This results in reduction in time required for entire manufacture of a semiconductor device, as compared to the manufacturing method according to the first preferred embodiment.

Additionally, with respect to formation of the contact holes 15, 65, the manufacturing method according to the second preferred embodiment requires an extra step of etching the stopper layer 17 (see FIG. 12) , as compared to formation of the contact holes 15, 16 in the manufacturing method according to the first preferred embodiment (see FIG. 1). Nonetheless, in the manufacturing method of the second preferred embodiment, there is no need to switch a manufacturing system after the step of etching stopper layer 17 because the step subsequent to the step of etching the stopper layer 17 is to etch the interlayer insulating film 14. By simply altering conditions for etching, it is possible to proceed from the step of etching the stopper layer 17 to the subsequent step of etching the interlayer insulating film 14. Accordingly, time increased due to addition of the step of etching the stopper layer 17 is much shorter than time reduced by utilizing the manufacturing method according to the second preferred embodiment (which is described above), and hardly affects time required for entire manufacture of a semiconductor device.

Third Preferred Embodiment

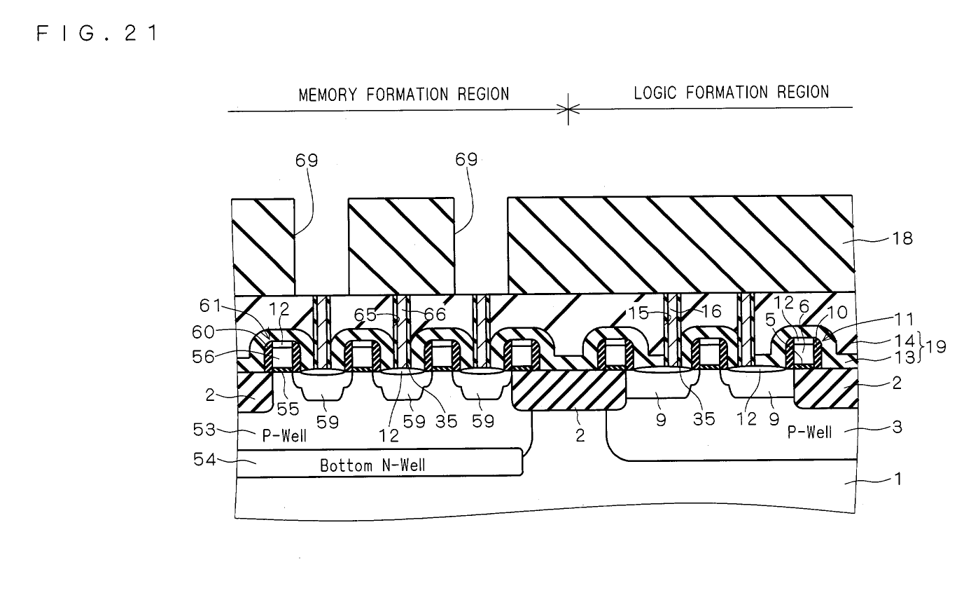

FIGS. 21 through 24 are sectional views for illustrating the method of manufacturing a semiconductor device according to the third preferred embodiment of the present invention, in order of occurrence of respective steps. According to the third preferred embodiment, a semiconductor device to be manufactured is a semiconductor device in which a memory device and a logic device are provided on one semiconductor substrate and a DRAM including a memory cell having a CUB structure and a dual gate salicide CMOS transistor, for example, are employed as the memory device and the logic device, respectively. Below, the method of manufacturing a semiconductor device according to the third preferred embodiment will be described with reference to FIGS. 21 through 24.

First, the steps described above with reference to FIGS. 26 through 30 are carried out. As a result, the structure illustrated in FIG. 30 is obtained. Subsequently, the steps described above with reference to FIGS. 1 through 3 are carried out, to obtain the structure illustrated in FIG. 3.

Next, the interlayer insulating film 18 is formed on an entire surface of the resultant structure, to be provided on the interlayer insulating film 14 and the contact plugs 16, 66 in the insulating layer 19. Subsequently, a photoresist (not illustrated) having a predetermined pattern of openings is formed on the interlayer insulating film 18. Then, the interlayer insulating film 18 is etched to be partially removed using the photoresist as a mask, which is followed by removal of the photoresist. For the process of etching the interlayer insulating film 18, anisotropic dry etching using a mixed gas of C₅F₈, O₂ and Ar is employed. As a result, the openings 69 by which some of the contact plugs 16 each being electrically connected to one of two adjacent source/drain regions 59 are formed in the interlayer insulating film 18 as illustrate in FIG. 21.

As generally known, the above described conditions employed for etching the interlayer insulating film 18 provide such a high etch selectivity of the interlayer insulating film 18 relative to the contact plugs 66 as not to allow the contact plugs 66 to be easily etched. Also, thickness uniformity of the interlayer insulating film 18 is increased, as well as an etch rate of the etching process performed on the interlayer insulating film 18 is stabilized to reduce an amount of over-etching occurring during the process of etching the interlayer insulating film 18. Hence, it is possible to prevent the openings 69 from reaching the gate electrodes 56 or the semiconductor substrate 1.

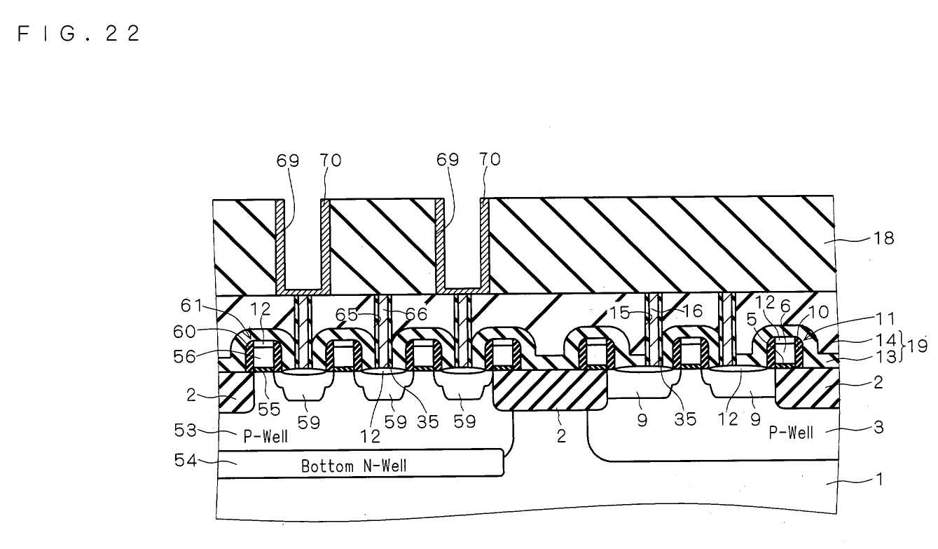

Next, the capacitors 82 of the memory cell of the DRAM which are in contact with the exposed ones of the contact plugs 66 are formed in the openings 69. More specifically, a metal film containing a high melting point metal such as ruthenium is formed on an entire surface of the resultant structure. Then, portions of the metal film located on the top face of the interlayer insulating film 18 are removed by anisotropic dry etching with the openings 69 being covered with a photoresist (not illustrated). As a result, the lower electrodes 70 of the capacitors 82 are formed in the openings 69 as illustrated in FIG. 22. Additionally, instead of anisotropic dry etching described above, a CMP process may alternatively be employed for removing the portions of the metal film located on the top face of the interlayer insulating film 18.

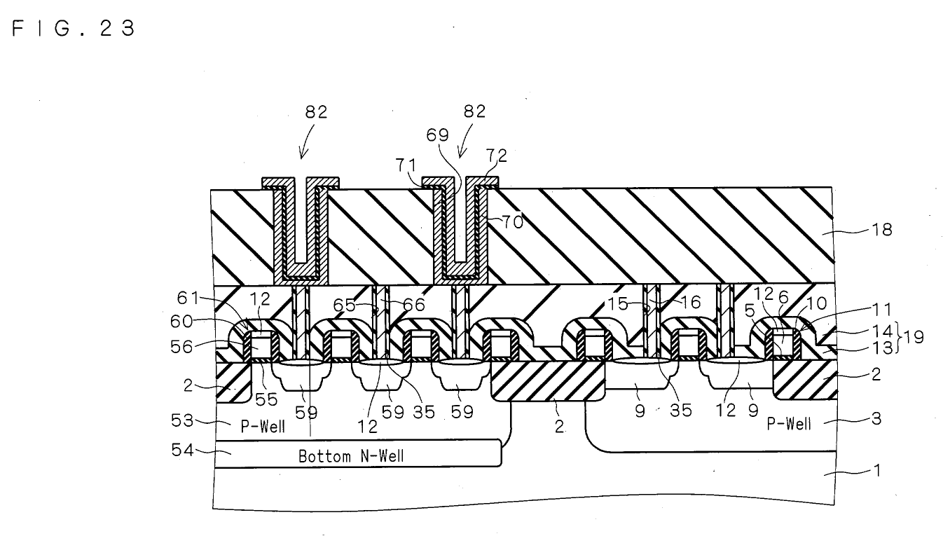

Next, an insulating film made of tantalum pentoxide, and subsequently, a metal film containing a high melting point metal such as ruthenium are formed on an entire surface of the resultant structure. Then, the formed insulating film and the formed metal film are patterned using a photoresist. As a result, the dielectric films 71 and the upper electrodes 72 of the capacitors 82 are formed, to complete the capacitors 82 in the openings 69 as illustrated in FIG. 23.

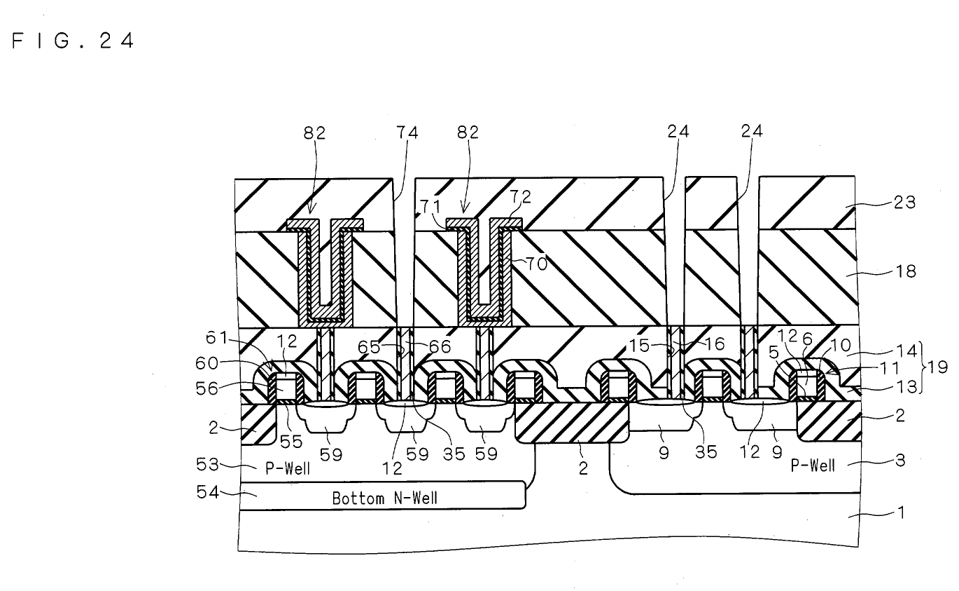

Next, referring to FIG. 24, the interlayer insulating film 23 is formed on an entire surface of the resultant structure, and then is planarized by a CMP process. Thus, the interlayer insulating film 23 covering the capacitors 82 is formed on the interlayer insulating film 18. Thereafter, the contact holes 24 and the contact holes 74 are formed in the interlayer insulating films 18 and 23. More specifically, a photoresist (not illustrated) having a predetermined pattern of openings is formed on the interlayer insulating film 23. Subsequently, the interlayer insulating films 18 and 23 are etched to be partially removed using the photoresist as a mask, which is followed by removal of the photoresist. For the process of etching the interlayer insulating films 18 and 23, anisotropic dry etching using a mixed gas of C₅F₈, O₂ and Ar is employed.

Thus, the contact holes 24 extending from the top face of the interlayer insulating film 23 and reaching the contact plugs 16, as well as the contact holes 74 extending from the top face of the interlayer insulating film 23 and reaching some of the contact plugs 66 which are not in contact with the capacitors 82, are formed.

As generally known, the above described conditions employed for etching the interlayer insulating films 18 and 23 provide such a high etch selectivity of the interlayer insulating films 18 and 23 relative to the contact plugs 16, 66 as not to allow the contact plugs 16, 66 to be easily etched. Also, thickness uniformity of each of the interlayer insulating films 18 and 23 is increased, as well as an etch rate of the etching process performed on the interlayer insulating films 18 and 23 is stabilized to reduce an amount of over-etching occurring during the process of etching the interlayer insulating films 18 and 23. Hence, it is possible to prevent the openings 69 from reaching the gate electrodes 56 or the semiconductor substrate 1 even if the contact holes 24, 74 are formed at positions shifted from desired positions. Further, contact holes extending from the top face of the interlayer insulating film 23 and reaching the upper electrodes 72 are formed in the interlayer insulating film 23, illustration of which is omitted in the drawings.

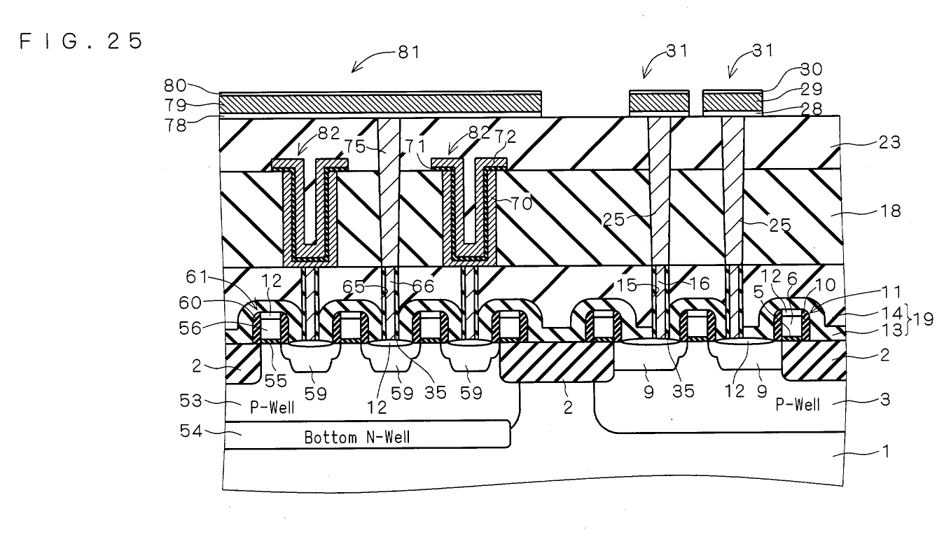

Next, the steps described above with reference to FIGS. 9 and 10 are carried out, to obtain the semiconductor device illustrated in FIG. 25.

By the foregoing steps, the memory device and the logic device are formed in the memory formation region and the logic formation region, respectively.

As described above, the method of manufacturing a semiconductor device according to the third preferred embodiment does not include formation of the stopper layer 17. The interlayer insulating film 18 is formed directly on the insulating layer 19 and the contact plugs 16, 66. Accordingly, a step of etching a stopper layer is not performed in forming the openings 69 or the contact holes 24, 74. In the method of manufacturing a semiconductor device according to the third preferred embodiment, while it is required that a manufacturing system be switched from an etching system to an ashing system in order to remove the photoresist after etching the interlayer insulating films, there is no need to further switch a manufacturing system from an ashing system to an etching system for forming the openings 69 or the contact holes 24, 74. Accordingly, time required for forming the openings 69 or the contact holes 24, 74 can be reduced, as compared to the manufacturing method according to the first preferred embodiment which requires that a manufacturing system be further switched from an ashing system to an etching system for forming the openings 69 or the contact holes 24, 74. This results in reduction in time required for entire manufacture of a semiconductor device, as compared to the manufacturing method according to the first preferred embodiment.

Moreover, unlike the manufacturing methods according to the first and second preferred embodiments, the manufacturing method according to the third preferred embodiment does not require the step of forming the stopper layer 17, which results in further reduction in time for entire manufacture of a semiconductor device.

While the invention has been shown and described in detail, the foregoing description is in all aspects illustrative and not restrictive. It is therefore understood that numerous modifications and variations can be devised without departing from the scope of the invention.

What is claimed is:

1. A method of manufacturing a semiconductor device comprising the steps of:
(a) preparing a semiconductor substrate having a first region where a memory device is to be formed and a second region where a logic device is to be formed, said semiconductor substrate having a top face on which a first gate structure including a first gate electrode is formed in a portion thereof included in said first region and a second gate structure including a second gate electrode is formed in a portion thereof included in said second region;
(b) forming an insulating layer which covers said first and second gate structures on said semiconductor substrate;
(c) forming first and second contact holes in portions of said insulating layer included in said first and second regions, respectively, so as to be located beside said first and second gate electrodes, respectively, by etching said insulating layer;
(d) forming an insulating film on a side face of each of said first and second contact holes;
(e) forming first and second contact plugs filling said first and second contact plugs, respectively, after said step (d); and
(f) forming a capacitor which is in contact with said first contact plug.

2. The method of manufacturing a semiconductor device according to claim 1, further comprising the step of:
(g) forming a stopper layer on said insulating layer between said steps (b) and (c),
wherein said stopper layer is etched together with said insulting layer so that said first and second contact holes are formed in said insulating layer and said stopper layer in said step (c),
said method further comprising the steps of:
(h) forming a first interlayer insulating film on said stopper layer and said first and second contact plugs between said steps (e) and (f);
(i) forming an opening by which said first contact plug is exposed in said first interlayer insulating film, by etching said first interlayer insulating film using each of said stopper layer and said first contact plug as an etch stop, prior to said step (f); and
(j) forming a third contact hole reaching said second contact plug in said first interlayer insulating film, by etching said first interlayer insulating film using each of said stopper layer and said second contact plug as an etch stop,
wherein said capacitor is formed so as to be provided in said opening in said step (f).

3. The method of manufacturing a semiconductor device according to claim 2, wherein
said semiconductor substrate which includes first and second source/drain regions is prepared in said step (a), said first and second source/drain regions being regularly spaced from each other in said portion of said top face included in said first region,
said first gate structure is provided on a portion of said semiconductor substrate between said first and second source/drain regions,
said first contact hole is formed so as to be located above said first source/drain region in said step (c),
said stopper layer is etched together with said insulating layer so that a fourth contact hole is further formed in said portion of said insulating layer included in said first region and a portion of said stopper layer included in said first region, said fourth contact hole being located beside said first electrode and above said second source/drain region in said step (c),
said insulating film is formed also on a side face of said fourth contact hole in said step (d),
said first contact plug is formed so as to be electrically connected to said first source/drain region in said step (e),
a third contact plug which fills said fourth contact hole and is electrically connected to said second source/drain region is further formed in said step (e),
said first interlayer insulating film is formed also on said third contact plug in said step (h),
said step (j) is carried out after said step (f),
said method further comprises the step of (k) forming a second interlayer insulating film covering said capacitor on said first interlayer insulating film between said steps (f) and (j),
said second interlayer insulating film is etched together with said first interlayer insulating film using each of said stopper layer, said second contact plug and said third contact plug as an etch stop, to form a fifth contact hole reaching said third contact plug, together with said third contact hole, in said first and second interlayer insulating films, in said step (j), and
said method further comprises the steps of:
(1) forming a fourth contact plug filling said fifth contact hole after said step (j); and
(m) forming a bit line in contact with said fourth contact plug on said second interlayer insulating film.

4. The method of manufacturing a semiconductor device according to claim 2, further comprising:
(g) forming a first interlayer insulating film on said insulating layer and said first and second contact plugs between said step (e) and (f);
(h) forming an opening by which said first contact plug is exposed in said first interlayer insulating film by etching said first interlayer insulating film, prior to said step (f); and
(i) forming a third contact hole reaching said second contact plug in said first interlayer insulating film by etching said first interlayer insulating film, wherein
said capacitor is formed so as to be provided in said opening in said step (f).

5. The method of manufacturing a semiconductor device according to claim 4, wherein
said semiconductor substrate which includes first and second source/drain regions is prepared in said step (a), said first and second source/drain regions being regularly spaced from each other in said portion of said top face included in said first region,
said first gate structure is provided on a portion of said semiconductor substrate between said first and second source/drain regions,
said first contact hole is formed so as to be located above said first source/drain region in said step (c),
a fourth contact hole is further formed in said portion of said insulating layer included in said first region so as to be located beside said first electrode and above said second source/drain region, by etching said insulating layer in said step (c);
said insulating film is formed also on a side face of said fourth contact hole in said step (d),
said first contact plug is formed so as to be electrically connected to said first source/drain region in said step (e),
a third contact plug which fills said fourth contact hole and is electrically connected to said second source/drain region is further formed in said step (e),
said first interlayer insulating film is formed also on said third contact plug in said step (g),
said step (i) is carried out after said step (f),
said method further comprises the step of (j) forming a second interlayer insulating film covering said capacitor on said first interlayer insulating film between said steps (f) and (i),
said second interlayer insulating film is etched together with said first interlayer insulating film, to form a fifth contact hole reaching said third contact plug, together with said third contact hole, in said first and second interlayer insulating films, in said step (i), and
said method further comprises the steps of:
(k) forming a fourth contact plug filling said fifth contact hole after said step (i); and
(1) forming a bit line in contact with said fourth contact plug on said second interlayer insulating film.
